(19) United States
(12) Patent Application Publication
(10) Pub. No.: US 2024/0138199 A1
(43) Pub. Date: Apr. 25, 2024

(54) LIGHT EMITTING DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR)

(73) Assignee: Samsung Display Co., LTD., Yongin-si (KR)

(21) Appl. No.: 18/465,205

(22) Filed: Sep. 11, 2023

(30) Foreign Application Priority Data
Oct. 23, 2022 (KR) 10-2022-0137367

(51) Int. Cl. H10K 59/122

(52) U.S. Cl. CPC H10K 59/122

(57) ABSTRACT

A light emitting display device includes a first light emitting electrode positioned on a substrate; a pixel defining film including a groove and an opening exposing a portion of the first light emitting electrode; a separator positioned within the groove of the pixel defining film and including a side wall having a reverse tapered structure; a light emitting layer positioned in the opening of the pixel defining film; and a second light emitting electrode separated by the separator.

### CROSS-REFERENCE TO RELATED APPLICATION

This application claims priority to and benefits of Korean Patent Application No. 10-2022-0137367 under 35 U.S.C. § 119, filed in the Korean Intellectual Property Office (KIPO) on Oct. 24, 2022, the entire contents of which are incorporated herein by reference.

### BACKGROUND

### 1. Technical Field

The disclosure relates to a light emitting display device.

### 2. Description of the Related Art

Display devices display images, and include liquid crystal displays (LCD), organic light emitting diode (OLED) displays, and the like. The display devices are used in a wide range of electronic devices, including mobile phones, navigation devices, digital cameras, e-books, portable game machines, and other types of terminals.

The OLED display, in contrast to the LCD, have grown in popularity given their ability to emit light independently of a separate light source, and as a result, their reduced thickness and weight. Additional benefits include low power consumption, high luminance, and advantageous processing speed.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments are to provide a light emitting display device including a separator positioned in a groove positioned in a pixel defining film.

Embodiments are to provide a light emitting display device that may connect a conductive layer by using an auxiliary connecting member having a protruding structure partially overlapping an opening for contact.

However, embodiments of the disclosure are not limited to those set forth herein. The above and other embodiments will become more apparent to one of ordinary skill in the art to which the disclosure pertains by referencing the detailed description of the disclosure given below.

An embodiment provides a light emitting display device including: a first light emitting electrode positioned on a substrate; a pixel defining film including a groove and an opening exposing a portion of the first light emitting electrode; a separator positioned within the groove of the pixel defining film and including a side wall having a reverse tapered structure; a light emitting layer positioned in the opening of the pixel defining film; and a second light emitting electrode separated by the separator.

The groove may have an undercut structure.

A lower surface of the separator may be positioned on an inner surface of the groove.

An upper surface of the pixel defining film and the side wall having the reverse tapered structure of the separator may be separated from each other.

The light emitting display device may further include an upper inorganic film positioned on the upper surface of the pixel defining film.

The upper inorganic film may not be positioned in the groove.

The upper inorganic film and the side wall having the reverse tapered structure of the separator may be separated from each other.

The light emitting display device may further include a driving element layer positioned between the substrate and the first light emitting electrode, wherein the driving element layer may include: a semiconductor layer positioned on the substrate; a first gate insulating film positioned on the semiconductor layer; a gate electrode positioned on the first gate insulating film; an interlayer insulating film covering the gate electrode; a connecting member positioned on the interlayer insulating film; and a planarization film covering the connecting member and including an opening exposing a portion of the connecting member.

The light emitting display device may further include an auxiliary member positioned on the planarization film and at least partially overlapping the opening of the planarization film in a plan view.

The first light emitting electrode may further include an opening. The auxiliary member may be positioned in the opening of the first light emitting electrode. The auxiliary member and the first light emitting electrode may be made of a same material.

The light emitting display device may further include a functional layer positioned between the first light emitting electrode and the light emitting layer and between the light emitting layer and the second light emitting electrode. In the auxiliary member, a stacked direction of the second light emitting electrode and a stacked direction of the functional layer may be different from each other.

The stacked direction of the functional layer may be inclined at an angle closer to a direction perpendicular to an upper surface of the substrate than the stacked direction of the second light emitting electrode.

In a portion of an area in which the second light emitting electrode and the connecting member overlap each other in a plan view, the functional layer may be positioned between the second light emitting electrode and the connecting member. In a remaining portion of the area in which the second light emitting electrode and the connecting member overlap each other in a plan view, the second light emitting electrode and the connecting member may be in direct contact with each other.

The light emitting display device may further include an auxiliary member forming another voltage connection and an auxiliary electrode separated by the separator. The driving element layer may further include a driving low voltage line. The auxiliary member and the first light emitting electrode may be made of a same material. The auxiliary electrode separated by the separator and the second light emitting electrode are made of a same material. The planarization film may further include another opening to electrically connect the auxiliary electrode and the driving low voltage line. A portion of the auxiliary electrode for second voltage connection may overlap the another opening of the planarization film in a plan view. Another embodiment provides a light emitting display device, including: a semiconductor layer positioned on a substrate; a first gate insulating film positioned on the semiconductor layer; a gate electrode positioned on the first gate insulating film; an interlayer insulating film covering the gate electrode; a connecting member positioned on the interlayer insulating film; a planarization film covering the connecting member and including an opening exposing a portion of the connecting member; a first light emitting electrode positioned on the planarization film; an auxiliary member positioned on the planarization film; a pixel defining film including an opening exposing a portion of the first light emitting electrode; a separator positioned on the pixel defining film; a light emitting layer positioned in the opening of the pixel defining film; and a second light emitting electrode positioned on the pixel defining film, the separator, and the light emitting layer. The auxiliary member may at least partially overlap the opening of the planarization film in a plan view.

The first light emitting electrode may further include an opening, the auxiliary member may be positioned in the opening of the first light emitting electrode. The auxiliary member and the first light emitting electrode may be made of a same material.

The light emitting display device may further include a functional layer positioned between the first light emitting electrode and the light emitting layer and between the light emitting layer and the second light emitting electrode. In the auxiliary member, a stacked direction of the second light emitting electrode and a stacked direction of the functional layer may be different from each other.

The stacked direction of the functional layer may be inclined at an angle closer to a direction perpendicular to an upper surface of the substrate than the stacked direction of the second light emitting electrode.

In a portion of an area in which the second light emitting electrode and the connecting member overlap each other in a plan view, the functional layer may be positioned between the second light emitting electrode and the connecting member. In a remaining portion of the area in which the second light emitting electrode and the connecting member overlap each other in a plan view, the second light emitting electrode and the connecting member may be in direct contact with each other.

The light emitting display device may further include a driving low voltage line; an auxiliary member forming another voltage connection; and an auxiliary electrode separated by the separator. The auxiliary member and the first light emitting electrode may be made of a same material. The auxiliary electrode and the second light emitting electrode may be made of a same material. The planarization film may further include another opening to electrically connect the auxiliary electrode and the driving low voltage line. A portion of the auxiliary electrode for second voltage connection may overlap the another opening of the planarization film in a plan view.

According to the embodiments, a separator may be positioned in a groove positioned in a pixel defining film, and a conductive layer stacked on the separator may be clearly separated based on the separator.

According to the embodiments, an auxiliary connecting member may have a protruding structure that partially overlaps an opening for contact in a plan view. Thus, even if two layers are continuously formed on the auxiliary connecting member, an angle of stacking each layer may be adjusted, and a conductive layer secondarily formed may be electrically connected to a lower conductive layer thereof.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 illustrates a schematic diagram of an equivalent circuit of a pixel of a light emitting display device according to an embodiment;

FIG. 2 illustrates a schematic plan view of a display area of a light emitting display device according to an embodiment;

FIG. 3 illustrates a schematic enlarged plan view of a portion of FIG. 2;

FIG. 4 illustrates a schematic cross-sectional view of the light emitting display device according to the embodiment of FIG. 2;

FIGS. 5 and 6 respectively illustrate a schematic enlarged cross-sectional view of a portion of FIG. 4;

FIGS. 7 and 8 schematically illustrate a manufacturing method for forming a pixel defining film of a light emitting display device according to an embodiment;

FIG. 9 illustrates a schematic image of an undercut structure generated during dry etching;

FIGS. 10 and 11 illustrate schematic views of a manufacturing method for forming a pixel defining film of a light emitting display device according to another embodiment;

FIGS. 12 to 15 illustrate schematic views of a structure through which a second voltage is transmitted;

FIG. 16 illustrates a schematic cross-sectional view of a light emitting display device according to a comparative example;

FIG. 17 schematically illustrates a photograph of a conductive layer around a separator of a comparative example;

FIG. 18 illustrates a schematic diagram of an equivalent circuit of a pixel of a light emitting display device according to another embodiment;

FIG. 19 illustrates a schematic plan view of a display area of the light emitting display device according to the embodiment of FIG. 18; and

FIG. 20 illustrates a schematic cross-sectional view of the light emitting display device according to the embodiment of FIG. 18.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

When an element such as a wire, layer, film, region, area, substrate, plate, or constituent element “is extended (or extends) in a first direction or second direction”, this does not mean only a straight shape extending straight in the corresponding direction, but may mean a structure that substantially extends in the first direction or the second direction, is partially bent, has a zigzag structure, or extends while having a curved structure.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Both an electronic device (e.g., a mobile phone, a TV, a monitor, a laptop computer, etc.) including a display device, or a display panel described in the specification, and an electronic device including a display device and a display panel manufactured by a manufacturing method described in the specification are not excluded from the scope of the specification.

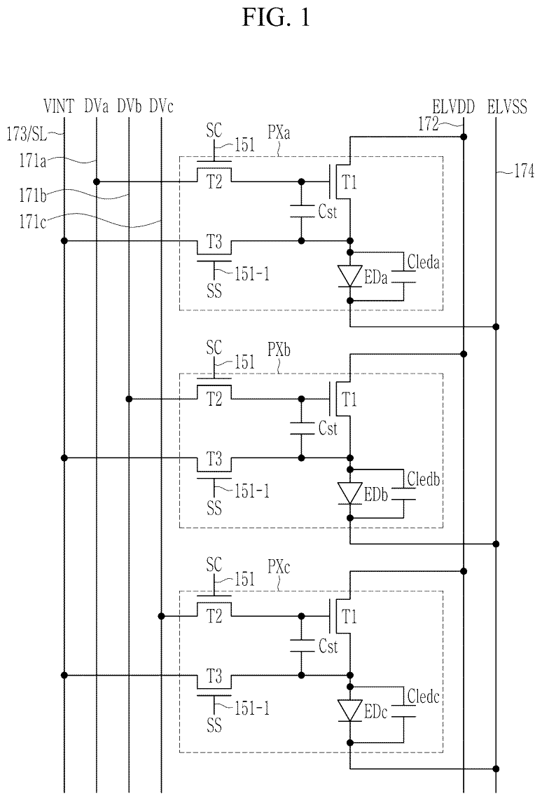

Hereinafter, a circuit structure of a pixel that may be included in a light emitting display device according to an embodiment is described with reference to FIG. 1.

FIG. 1 illustrates a schematic diagram of an equivalent diagram of a pixel of a light emitting display device according to an embodiment.

FIG. 1 illustrates a circuit diagram of three pixels PXa, PXb, and PXc.

Referring to FIG. 1, pixels may include a first pixel PXa, a second pixel PXb, and a third pixel PXc. Each of the first pixel PXa, the second pixel PXb, and the third pixel PXc may include transistors T1, T2, and T3, a storage capacitor Cst, and light emitting elements EDa, EDb, and EDc. Here, a pixel PXa, PXb, or PXc may include a light emitting element EDa, EDb, or EDc and a pixel driver PCa, PCb, or PCc. Referring to FIG. 1, the pixel driver PCa, PCb, or PCc may correspond to a portion excluding the light emitting element EDa, EDb, or EDc in each of the pixels PXa, PXb, and PXc, and include the transistors T1, T2, and T3 and the storage capacitor Cst. In some embodiments, the pixel driver PCa, PCb, or PCc may include a capacitor Cleda, Cledb, or Cledc (e.g., a light emitting capacitor) electrically connected to ends (e.g., both ends) of the light emitting element EDa, EDb, or EDc, and the light emitting element Eda, EDb, or EDc may include the light emitting capacitor Cleda, Cledb, or Cledc. For example, the light emitting capacitor Cleda, Cledb, or Cledc may not be included in the pixel driver PC1, PCb, or PCc.

The transistors T1, T2, and T3 may include a driving transistor T1 (also referred to as a first transistor) and two switching transistors T2 and T3, and the two switching transistors T2 and T3 may be classified into an input transistor T2 (also referred to as a second transistor) and an initialization transistor T3 (also referred to as a third transistor). Each of the transistors T1, T2, and T3 may include a gate electrode, a first electrode, a second electrode, and a semiconductor layer including a channel. Thus, a current may flow or may not flow in the channel of the semiconductor layer according to a voltage of the gate electrode. Depending on voltages applied to respective transistors T1, T2, and T3, one of the first electrode and the second electrode may be a source electrode, and the other thereof may be a drain electrode.

The gate electrode of the driving transistor T1 may be electrically connected to an end of the storage capacitor Cst, and be also electrically connected to the second electrode (output side electrode) of the input transistor T2. The first electrode of the driving transistor T1 may be electrically connected to a driving voltage line 172 that transmits a first voltage ELVDD (e.g., a driving voltage). The second electrode of the driving transistor T1 may be electrically connected to an anode of the light emitting element EDa, EDb, or EDc, the other end of the storage capacitor Cst, the first electrode of the initialization transistor T3, and an end of the light emitting capacitor Cleda, Cledb, or Cledc. The gate electrode of the driving transistor T1 may receive a data voltage DVa, DVb, or DVc according to a switching operation of the input transistor T2, and a driving current may be supplied to the light emitting element EDa, EDb, or EDc according to the voltage of the gate electrode thereof. The storage capacitor Cst may store and maintain the voltage of the gate electrode of the driving transistor T1.

The gate electrode of the input transistor T2 may be electrically connected to a first scan signal line 151 that transmits a first scan signal SC. The first electrode of the input transistor T2 may be electrically connected to a data line 171a, 171b, or 171c that transmits the data voltage DVa, DVb, or DVc, and the second electrode of the input transistor T2 may be electrically connected to one end of the storage capacitor Cst and the gate electrode of the driving transistor T1. The data lines 171a, 171b, and 171c may transmit different data voltages DVa, DVb, and DVc, respectively, and the input transistors T2 of the pixels PXa, PXb, and PXc may be respectively and electrically connected to different data lines 171a, 171b, and 171c. The gate electrodes of the input transistors T2 of the pixels PXa, PXb, and PXc may be electrically connected to the same first scan line 151 and receive the same first scan signal SC at the same timing. Even in case that the input transistors T2 of the pixels PXa, PXb, and PXc may be simultaneously turned on by the first scan signal SC of the same timing, the different data voltages DVa, DVb, and DVc may be applied to the gate electrodes of the driving transistors T1 of the pixel PXa, PXb, and PXc and one end of the storage capacitor Cst through the different data lines 171a, 171b, and 171c.

In FIG. 1, the gate electrodes of the initialization transistor T3 and the input transistor T2 may receive different scan signals.

The gate electrode of the initialization transistor T3 may be electrically connected to a second scan signal line 151-1 that transmits a second scan signal SS. The first electrode of the initialization transistor T3 may be electrically connected to the another end of the storage capacitor Cst, the second electrode of the driving transistor T1, the anode of the light emitting element EDa, EDb, or EDc, and an end of the light emitting capacitor Cleda, Cledb, or Cledc. The second electrode of the initialization transistor T3 may be electrically connected to an initialization voltage line 173 that transmits an initialization voltage VINT. The initialization transistor T3 may be turned on according to the second scan signal SS and transmit the initialization voltage VINT to the anode of the light emitting element EDa, EDb, or EDc, one end of the light emitting capacitor Cleda, Cledb, or Cledc, and the other end of the storage capacitor Cst to initialize the voltage of the anode of the light emitting element EDa, EDb, or EDc.

The initialization voltage line 173 may sense a voltage of the anode of the light emitting element EDa, EDb, or EDc before the initialization voltage VINT is applied. Thus, the initialization voltage line 173 may serve as a sensing wire SL. In case that the voltage of the anode of the light emitting element Eda, EDb, or EDc is sensed, the sensing wire SL may check whether the anode voltage is maintained at a target voltage. The sensing operation and the initialization operation of transmitting the initialization voltage VINT may be performed separately in time. For example, the initialization operation may be performed after the sensing operation is performed.

In the embodiment of FIG. 1, turn-on periods of the initialization transistor T3 and of the input transistor T2 may be separated. For example, the turn-on period of the initialization transistor T3 and the turn-on period of the input transistor T2 may be different from each other. Thus, a writing operation performed by the input transistor T2 and an initialization operation (and/or sensing operation) performed by the initialization transistor T3 may be performed at different timings.

One end of the storage capacitor Cst may be electrically connected to the gate electrode of the driving transistor T1 and the second electrode of the input transistor T2. The other end of the storage capacitor Cst may be electrically connected to the first electrode of the initialization transistor T3, the second electrode of the driving transistor T1, the anode of the light emitting element EDa, EDb, or EDc, and one end of the light emitting capacitor Cleda, Cledb, or Cledc.

An output current of the driving transistor T1 may be transmitted to the anode of the light emitting element EDa, EDb, or EDc. The cathode of the light emitting element EDa, EDb, or EDc may receive a second voltage ELVSS (e.g., a driving low voltage) through a driving low voltage line 174. The light emitting element EDa, EDb, or EDc may emit light according to the output current of the driving transistor T1 and display a grayscale.

The light emitting part capacitors Cleda, Cledb, and Cledc may be formed at respective ends of the light emitting elements EDa, EDb, and EDc. Thus, voltages at respective ends of the light emitting elements EDa, EDb, and EDc may be maintained constant. Therefore, the light emitting elements EDa, EDb, and EDc may display a constant luminance.

Hereinafter, an operation of a pixel having the circuit as shown in FIG. 1 is briefly described.

FIG. 1 illustrates the embodiment in which each transistor T1, T2, or T3 is an N-type transistor, and each transistor T1, T2, or T3 is turned on in case that a high level voltage is applied to the gate electrode thereof. However, in some embodiments, all or some of respective transistors T1, T2, and T3 may be a P-type transistor or an N-type transistor.

A frame may start in case that a light emitting period ends. The second scan signal SS of a high level may be supplied to turn on the initialization transistor T3. In case that the initialization transistor T3 is turned on, an initialization operation and/or a sensing operation may be performed.

The embodiment in which both the initialization operation and the sensing operation are performed is described below.

The sensing operation may be performed before the initialization operation is performed. For example, in case that the initialization transistor T3 is turned on, the initialization voltage line 173 may serve as the sensing wire SL and sense a voltage of the anode of the light emitting element EDa, EDb, or EDc. In case that the voltage of the anode of the light emitting element EDa, EDb, or EDc is sensed, the sensing wire SL may check whether the anode voltage is maintained at a target voltage.

The initialization operation may be performed, and the voltages of the other end of the storage capacitor Cst, the second electrode of the driving transistor T1, and the anode of the light emitting element EDa, EDb, or EDc may be changed to the initialization voltage VINT transmitted from the initialization voltage line 173. Thus, the initialization operation may be performed.

As described above, the sensing operation and the initialization operation for transmitting the initialization voltage VINT may be time-divided and performed. Thus, the pixel may perform various operations while using a minimum number of transistors and reducing an area occupied by the pixel. As a result, a resolution of the display panel may be improved.

The first scan signal SC may also be applied and changed to a high level together with the initialization operation. In other embodiments, the application of the first scan signal SC and the initialization operation may be performed at separate timing. Thus, the input transistor T2 may be turned on, and a writing operation may be performed. For example, the data voltage DVa, DVb, or DVc from the data line 171a, 171b, or 171c through the turned-on input transistor T2 may be inputted and stored to the gate electrode of the driving transistor T1 and one end of the storage capacitor Cst.

The data voltage DVa, DVb, or DVc and the initialization voltage VINT may be applied to respective ends of the storage capacitor Cst by the initialization operation and the writing operation, respectively. In case that the initialization transistor T3 is turned on, even if an output current is generated from the driving transistor T1, the output current may be outputted to the outside through the initialization transistor T3 and the initialization voltage line 173. Thus, the output current may not be inputted to the anode of the light emitting element EDa, EDb, or EDc. In some embodiments, during the writing period in which the high level first scan signal SC is supplied, the first voltage ELVDD may be applied as a low level voltage, or the second voltage ELVSS may be applied as a high level voltage, so that it is possible to prevent a current from flowing through the light emitting element EDa, EDb, or EDc.

In case that the first scan signal SC is changed to a low level, the driving transistor T1 may generate and output an output current by the high level first voltage ELVDD applied to the driving transistor T1 and the gate voltage of the driving transistor T1 stored in the storage capacitor Cst. The output current of the driving transistor T1 may be inputted to the light emitting element EDa, EDb, or EDc, and the light emitting element EDa, EDb, or EDc may emit light (e.g., a light emitting period).

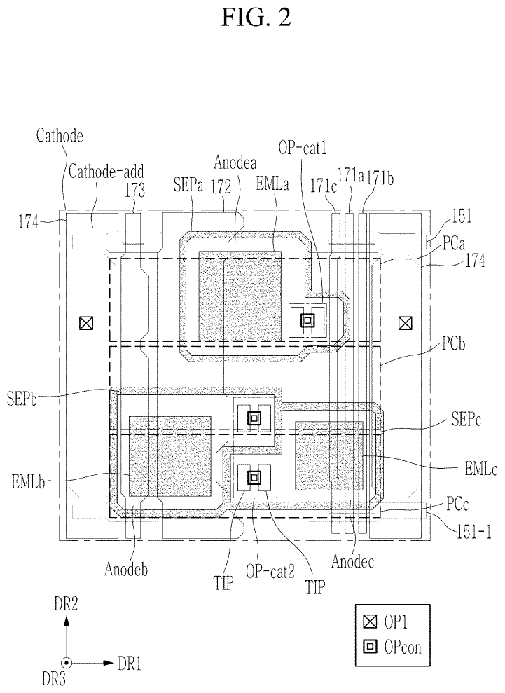

A planar structure and a cross-sectional structure of a light emitting display device including the pixel having the circuit structure as described above is described with reference to FIGS. 2 to 6.

An overall planar structure thereof is described with reference to FIG. 2.

FIG. 2 illustrates a schematic plan view of a display area of a light emitting display device according to an embodiment.

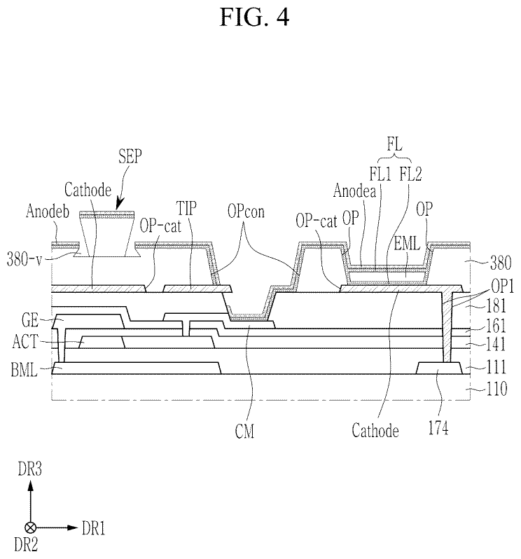

In FIG. 2, an area of each of the pixel drivers PCa, PCb, and PCc included in the pixel is shown with a dotted line, and a cathode Cathode and respective anodes Anodea, Anodeb, and Anodec among the light emitting elements EDa, EDb, and EDc electrically connected to the pixel drivers PCa, PCb, and PCc are shown. Here, respective anodes Anodea, Anodeb, and Anodec of the light emitting elements EDa, EDb, and EDc may be separated by separators SEPa, SEPb, and SEPc. For example, respective anodes Anodea, Anodeb, and Anodec may be positioned in the separators SEPa, SEPb, and SEPc in FIG. 2. The cathode Cathode of the embodiment may be positioned below a pixel defining film 380 (e.g., refer to FIG. 4). For example, referring to FIGS. 2 and 4, among a light emitting layer EML (e.g., refer to FIG. 4), the light emitting element may include the anodes, the cathodes, and the light emitting layer. The cathode Cathode may be positioned below the light emitting layer, and the anodes Anodea, Anodeb, and Anodec may be positioned on the light emitting layer.

In FIG. 2, the cathode Cathode may have openings OP-cat1 and OP-cat2 (e.g., contact openings) and may be formed in an entire area (e.g., an entire area of the display area). As a result, the cathode Cathode may be entirely formed in an area excluding the openings OP-cat1 and OP-cat2. The anodes Anodea, Anodeb, and Anodec positioned on the light emitting layer may receive a current from the pixel circuit parts PCa, PCb, and PCc positioned under the pixel defining film 380 through the openings OP-cat1 and OP-cat2 of the cathode Cathode.

Hereinafter, a structure of FIG. 2 is described in detail.

FIG. 2 illustrates a portion of a display area, and each pixel may include a light emitting element and a pixel driver. FIG. 2 mainly illustrates the anodes Anodea, Anodeb, and Anodec, light emitting layers EMLa, EMLb, and EMLc, the cathode Cathode, the separators SEPa, SEPb, and SEPc, and the pixel drivers PCa, PCb, and PCc. Here, the anodes Anodea, Anodeb, and Anodec, the light emitting layers EMLa, EMLb, and EMLc, and the cathode Cathode may be combined with one another and configure a light emitting element. The light emitting element and the pixel drivers PCa, PCb, and PCc may be combined with one another and configure a pixel. The light emitting layers EMLa, EMLb, and EMLc in FIG. 2 may be light emitting layers EMLa, EMLb, and EMLc positioned in the opening positioned in the pixel defining film 380 (e.g., refer to FIG. 4), and the light emitting layers EMLa, EMLb, and EMLc positioned in the opening of the pixel defining film 380 (e.g., refer to FIG. 4) may be referred to as a light emitting area.

The separators SEPa, SEPb, and SEPc may be positioned on a groove positioned in the pixel defining film 380 (e.g., refer to FIG. 4), and openings OP1 and OPcon may be openings positioned in the pixel defining film 380 (e.g., refer to FIG. 4) with an insulating film positioned thereunder.

In FIG. 2, a total of three adjacent pixel drivers PCa, PCb, and PCc may be schematically illustrated by dotted lines.

Each of the three pixel drivers PCa, PCb, and PCc positioned in FIG. 2 may have a structure extending in a first direction DR1, and the three pixel drivers may be the pixel drivers PCa, PCb, and PCc corresponding to pixels displaying the three primary colors of light, respectively. The pixel drivers PCa, PCb, and PCc may have various structures, and according to the embodiment, may have the same circuit structure as that of FIG. 1.

In FIG. 2, a portion of a wire additionally and electrically connected to the pixel drivers PCa, PCb, and PCc is illustrated. In FIG. 2, the first scan signal line 151 and the second scan signal line 151-1 extending in the first direction DR1 are shown, and the data lines 171a, 171b, and 171c, the driving voltage line 172, the initialization voltage line 173, and the driving low voltage line (e.g., a second driving voltage line) extending in a second direction DR2 are also shown.

The pixel drivers PCa, PCb, and PCc may be commonly and electrically connected to the first scan signal line 151, the second scan signal line 151-1, the driving voltage line 172, the initialization voltage line 173, and the driving low voltage line 174. The first pixel driver PCa may be electrically connected to the first data line 171a. The second pixel driver PCb may be electrically connected to the second data line 171b. The third pixel driver PCc may be electrically connected to the third data line 171c.

Each of the pixel drivers PCa, PCb, and PCc may correspond to one third of a planar area partitioned by the first scan signal line 151, the second scan signal line 151-1, and the driving low voltage line 174.

In the embodiment of FIG. 2, the first pixel driver PCa may be electrically connected to the first anode Anodea through the opening OPcon (e.g., a connector opening) and the opening OP-cat1 positioned in the cathode Cathode. The second pixel driver PCb may be electrically connected to the second anode Anodeb through the opening OPcon and the opening OP-cat2 positioned in the cathode Cathode. The third pixel driver PCc may be electrically connected to the third anode Anodec through the opening OPcon and the opening OP-cat2 positioned in the cathode Cathode.

In the embodiment of FIG. 2, the first light emitting element may include the first anode Anodea, the first light emitting layer EMLa, and the cathode Cathode. The second light emitting element may include the second anode Anodeb, the second light emitting layer EMLb, and a cathode Cathode. The third light emitting element may include the third anode Anodec, the third light emitting layer EMLc, and the cathode Cathode.

The cathode Cathode may be formed in the display area (e.g., the entire display area excluding the openings OP-cat1 and OP-cat2). The cathode Cathode may be electrically connected to the driving low voltage line 174 positioned therebelow through the opening OP1 and receive the second voltage ELVSS.

The separators SEPa, SEPb, and SEPc may be positioned in a groove 380-v (e.g., refer to FIG. 4) of the pixel defining film 380 (e.g., refer to FIG. 4), and may have a reversely tapered side wall. Each of the separators SEPa, SEPb, and SEPc may form a closed curved line in a plan view, and the anodes may be separated based on the separators SEPa, SEPb, and SEPc. The separators SEPa, SEPb, and SEPc may be separated from each other at a distance (e.g., a predetermined or selectable distance). For example, referring to FIG. 2, the separators SEPa, SEPb, and SEPc may share at least some of the separators SEPa, SEPb, and SEPc with each other. In the embodiment of FIG. 2, the second separator SEPb and the third separator SEPc may share a portion with each other.

In a plan view, the first anode Anodea may be positioned inside the first separator SEPa, the second anode Anodeb may be positioned inside the second separator SEPb, and the third anode Anodec may be positioned inside the third separator SEPc. An auxiliary electrode Cathode-add may be disposed at the outside of the separators SEPa, SEPb, and SEPc. The auxiliary electrode Cathode-add and the anodes Anodea, Anodeb, and Anodec may be made of a same material. The auxiliary electrode Cathode-add may receive the second voltage ELVSS which is the same voltage applied to the cathode. In some embodiments, the auxiliary electrode Cathode-add may be applied with different voltages from an adjacent auxiliary electrode or may be a floating electrode (or may be floated).

The first anode Anodea and the first light emitting layer EMLa may be positioned inside the first separator SEPa in a plan view. The first anode Anodea, the first light emitting layer EMLa, and the cathode Cathode positioned under the first light emitting layer EMLa may configure a first light emitting element. The first anode Anodea of the first light emitting element may be electrically connected to the first pixel driver PCa through the opening OP-cat1 positioned in the cathode Cathode, and may receive a current from the first pixel driver PCa.

The second anode Anodeb and the second light emitting layer EMLb may be positioned inside the second separator SEPb in a plan view. The second anode Anodeb, the second light emitting layer EMLb, and the cathode Cathode positioned under the second light emitting layer EMLb may configure a second light emitting element. The second anode Anodeb of the second light emitting element may be electrically connected to the second pixel driver PCb through the opening OP-cat2 positioned at the cathode Cathode, and may receive a current from the second pixel driver PCb.

The third anode Anodec and the third light emitting layer EMLc may be positioned inside the third separator SEPc in a plan view. The third anode Anodec, the third light emitting layer EMLc, and the cathode Cathode positioned under the third light emitting layer EMLc may configure a third light emitting element. The third anode Anodec of the first light emitting element may be electrically connected to the third pixel driver PCc through the opening OP-cat2 positioned in the cathode Cathode, and may receive a current from the third pixel driver PCc.

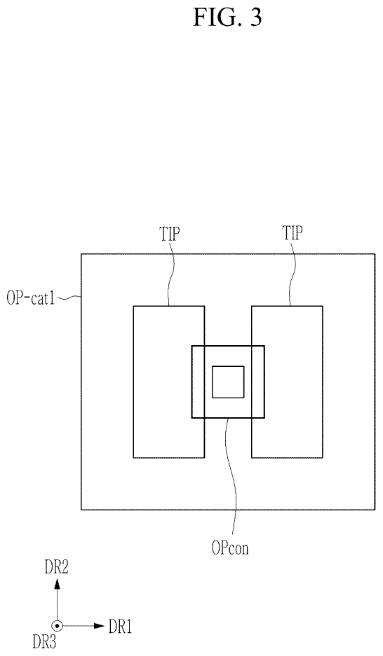

Referring to FIG. 2, the pixel drivers PCa, PCb, and PCc may be electrically connected to the anodes Anodea, Anodeb, and Anodec through the openings OPcon in the openings OP-cat1 and OP-cat2 positioned in the cathode Cathode in a plan view. An auxiliary member TIP may be formed on the opening OPcon. The auxiliary member TIP and the cathode Cathode may be made of a same material. The auxiliary member TIP may have a tip structure. The tip structure of the auxiliary member TIP may at least partially overlap the opening OPcon in a plan view and protrude in a cross-sectional view. The auxiliary member TIP and a structure around the auxiliary member TIP are enlarged and illustrated in FIG. 3.

FIG. 3 illustrates a schematic enlarged plan view of a portion of FIG. 2.

Referring to FIG. 3, the auxiliary member TIP may be positioned in the opening OP-cat2 positioned on the cathode Cathode in a plan view. The auxiliary member TIP and the cathode Cathode may be made of a same material. The auxiliary member TIP may at least partially overlap the opening OPcon in a plan view. The auxiliary member TIP may overlap only at least a portion of the opening OPcon in a plan view and may not cover all of the opening OPcon.

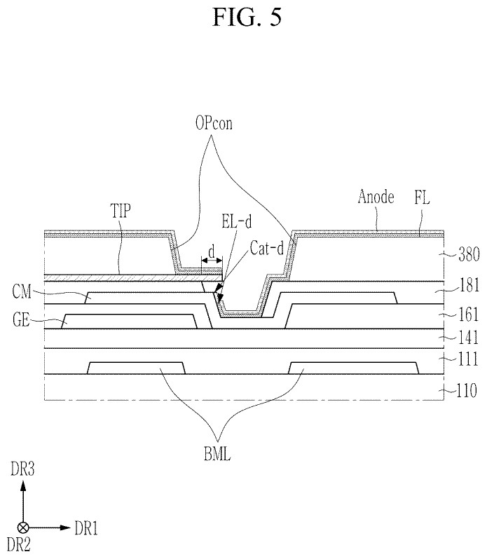

The auxiliary member TIP may be positioned at an upper portion of the opening OPcon. Referring to FIGS. 4 and 5, the auxiliary member TIP may protrude at the upper portion of a portion of the opening OPcon, may not be formed along a side wall of the opening OPcon, and may protrude at an angle equivalent to the horizontal direction from the side wall of the opening OPcon. As described above, since the auxiliary member TIP has a structure protruding at the upper portion of the opening OPcon, in case that layers (e.g., a functional layer FL and an anode Anode of FIG. 5) are positioned in the opening OPcon, each of the layers may be adjusted and formed (e.g., appropriately adjusted and formed) below the auxiliary member TIP. Thus, the layers may be electrically connected to the anode Anode. The auxiliary member TIP is described in more detail with reference to FIG. 5.

A cross-sectional structure of the light emitting display device having the planar structure of FIGS. 2 and 3 as described above is described in detail with reference to FIGS. 4 to 6 as follows.

Hereinafter, an overall cross-sectional structure of the light emitting display device is described with reference to FIG. 4.

FIG. 4 illustrates a schematic cross-sectional view of the light emitting display device according to the embodiment of FIG. 2.

In the cross-sectional structure of FIG. 4, the light emitting element may correspond to a light emitting layer EML positioned within an opening OP of the pixel defining film 380, and the opening OP of the pixel defining film 380 is also referred to as a light emitting area.

FIG. 4 illustrates a light emitting area (e.g., a light emitting layer EML) positioned within the opening OP of the pixel defining film 380, and illustrates a path through which the transistor currents of the pixel drivers PCa, PCb, and PCc (e.g., refer to FIG. 2) are transmitted through the opening OPcon to the anode Anodea positioned on the light emitting layer EML, and a separator SEP positioned in a groove 380-v positioned in the pixel defining film 380.

In the cross-sectional view of FIG. 4, a layer that corresponds to the cathode Cathode, the pixel defining film 380, an intermediate layer including the functional layer FL and the light emitting layer EML, and the anodes Anodea and Anodeb may also be referred to as a light emitting element layer. For example, the light emitting element layer may include the cathode Cathode, the pixel defining film 380, the intermediate layer, and the anodes Anodea and Anodeb. A planarization film 181 positioned below the light emitting element layer (e.g., the cathode Cathode), a conductive layer configuring a transistor and a capacitor, a semiconductor layer, and an insulating layer positioned therebelow, may also be referred to as a driving element layer. For example, the driving element layer may include the planarization film 181, the conductive layer of the transistor and the capacitor, the semiconductor layer, and the insulating layer.

In FIG. 4, the structure of the driving element layer is simplified and a transistor is illustrated. The structure of the driving element layer from a substrate 110 to the planarization film 181 is briefly described as follows.

The substrate 110 may include a material that has a rigid characteristic such as glass. Thus, the substrate 110 may not be bent. In other embodiments, the substrate 110 may include a flexible material such as plastic or polyimide that may be bent. In case that the substrate 110 is a flexible substrate, a two-layered structure of a barrier layer made of a polyimide and an inorganic insulating material thereon may be repeatedly formed.

A lower shielding layer BML containing a metal may be positioned on the substrate 110, and the lower shielding layer BML may overlap the channel of one of the transistors positioned in the pixel drivers PCa, PCb, and PCc included in the pixel in a plan view. In the embodiment of FIG. 4, the second voltage ELVSS may be applied to the driving low voltage line 174. The driving low voltage line 174 and the lower shielding layer BML may be positioned on a same layer. In some embodiments, the lower shielding layer BML may be omitted, and the driving low voltage line 174 may be positioned on another conductive layer.

The substrate 110, the lower shielding layer BML, and the driving low voltage line 174 may be covered by a buffer layer 111. The buffer layer 111 may block penetration of impurity into a semiconductor layer ACT, and may be an inorganic insulating layer including at least one of a silicon oxide (SiOₓ), a silicon nitride (SiNₓ), and a silicon oxynitride (SiONₓ).

The semiconductor layer ACT formed of a silicon semiconductor (e.g., a polycrystalline semiconductor (P—Si)) or an oxide semiconductor may be positioned on the buffer layer 111. The semiconductor layer ACT may be a semiconductor layer positioned on the pixel drivers PCa, PCb, and PCc included in the pixel, and may include a channel of a transistor including a driving transistor and first and second areas positioned at sides (e.g., both sides) thereof. The channel of the transistor may be a portion of the semiconductor layer ACT that overlaps a gate electrode GE of the semiconductor layer ACT in a plan view, and the first area and the second area may be portions of the semiconductor layer ACT that do not overlap the gate electrode GE in a plan view. For example, the first and second areas positioned at the sides of the channel of the semiconductor layer ACT may not be covered by the gate electrode GE. The first and second areas of the semiconductor layer ACT may be plasma treated or doped and may be electrically conductive. Thus, the first and second areas of the semiconductor layer ACT may be able to serve as the first and second electrodes of the transistor.

A first gate insulating film 141 may be positioned on the semiconductor layer ACT. The first gate insulating film 141 may be an inorganic insulating film including at least one of a silicon oxide (SiOₓ), a silicon nitride (SiNₓ), and a silicon oxynitride (SiONₓ).

A first gate conductive layer including the gate electrode GE of the transistor positioned in the pixel drivers PCa, PCb, and PCc may be positioned on the first gate insulating film 141. In the first gate conductive layer, a scan line may be formed in addition to the gate electrodes GE of the transistors positioned in the pixel drivers PCa, PCb, and PCc. The first gate conductive layer may include electrodes of capacitors positioned in the pixel drivers PCa, PCb, and PCc. For example, the first gate conductive layer may include the gate electrodes GE of the transistors, the electrodes of the capacitors, and the scan line. The first gate conductive layer may include at least one of metal of aluminum (Al), copper (Cu), molybdenum (Mo), and titanium (Ti). For example, the first gate conductive layer may include a metal alloy thereof. The first gate conductive layer may be formed as a single layer or a multilayer.

After the first gate conductive layer is formed, a plasma treatment or doping process may be performed on the exposed area of the first conductive layer and the exposed area of the first semiconductor layer may be electrically conductive. For example, the semiconductor layer ACT covered by the gate electrode GE may not be electrically conductive, and a portion of the semiconductor layer ACT not covered by the gate electrode GE may have the same characteristics as the conductive layer (e.g., may be electrically conductive).

An interlayer insulating film 161 may be positioned on the first gate conductive layer and the first gate insulating film 141. The first interlayer insulating film 161 may include an inorganic insulating film including at least one of a silicon oxide (SiOₓ), a silicon nitride (SiNₓ), and a silicon oxynitride (SiONₓ) In some embodiments, the inorganic insulating material may be thickly formed therein. In some embodiments, the interlayer insulating film 161 may be formed as an organic insulating film and may include at least one of a polyimide, a polyamide, an acryl resin, benzocyclobutene, and a phenol resin.

A data conductive layer including a connecting member CM that transmits an output current of the transistor to an electrode (e.g., the anode Anodea) of the light emitting element may be positioned on the interlayer insulating film 161. The data conductive layer may further include a connecting member for electrically connecting another part. The data conductive layer may include at least one metal of aluminum (Al), copper (Cu), molybdenum (Mo), and titanium (Ti). In other embodiments, the data conductive layer may include a metal alloy thereof. For example, the data conductive layer may be formed as a single layer or a multilayer.

The planarization film 181 may be positioned on the data conductive layer and the interlayer insulating film 161. The planarization layer 181 may include the opening OPcon that exposes the connecting member CM and overlaps a portion of the connecting member CM in a plan view. The opening OP1 that exposes the driving low voltage line 174 and overlaps a portion of the driving low voltage line 174 in a plan view may be formed in the insulating film (e.g., the buffer layer 111, the first gate insulating film 141, the interlayer insulating film 161, the planarization film 181, or the like) included in the driving element layer in FIG. 4. The planarization film 181 may be formed as an organic insulating film, and may include at least one of a polyimide, a polyamide, an acryl resin, benzocyclobutene, and a phenol resin.

The structure of the driving element layer has been described above, and the structure of the light emitting element layer is described in detail below.

A first electrode layer including the cathode Cathode and the auxiliary member TIP may be formed on the interlayer insulating film 161. The auxiliary member TIP may be positioned within the opening OP-cat of the cathode Cathode and electrically separated from the cathode Cathode. A portion of the cathode Cathode may overlap the light emitting layer EML positioned within the opening OP of the pixel defining film 380 and overlap the light emitting area in a plan view. Thus, a light emitting element may be formed.

The first electrode layer may be formed as a single layer including a transparent conductive oxide film or a metal material, or a multi-layer including the above-described materials. The transparent conductive oxide film of the first electrode layer may include at least one of an indium tin oxide (ITO), a poly-ITO, an indium zinc oxide (IZO), an indium gallium zinc oxide (IGZO), and an indium tin zinc oxide (ITZO). The metal material of the first electrode layer may include at least one of silver (Ag), molybdenum (Mo), copper (Cu), gold (Au), and aluminum (Al).

The pixel defining film 380 including the openings OP and OPcon may be formed on the first electrode layer.

The opening OP of the pixel defining film 380 may be a portion corresponding to the light emitting element and/or the light emitting area, and light may be emitted from the light emitting layer EML positioned therein. The opening OP of the pixel defining film 380 may expose a portion of the cathode Cathode.

The opening OPcon of the pixel defining film 380 may be an opening for exposing a portion of the auxiliary member TIP and the connecting member CM positioned on the driving element layer. For example, the opening OPcon of the pixel defining film 380 may be an opening for electrically connecting the connecting member CM and the anode Anodea.

The pixel defining film 380 may further include the groove 380-v, and a lower surface of the separator SEP may be in contact with the inside of the groove 380-v and an upper portion of the inner surface of the groove 380-v.

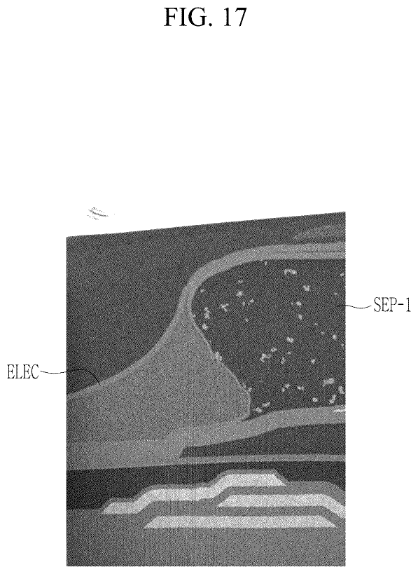

The separator SEP may separate two anodes Anodea and Anodeb and include at least one side wall of a reverse tapered structure. Although the separator SEP has the reverse tapered side wall and the conductive layer positioned thereon is separated, the conductive layer disposed on the separator SEP may not be separated as shown in FIG. 17 during a process. However, in the embodiment, the lower surface of the separator SEP may be positioned in the groove 380-v of the pixel defining film 380, and the upper surface of the pixel defining film 380 and the reverse tapered side wall of the separator SEP may be separated from each other. For example, an inner side of the groove 380-v may be positioned between the upper surface of the pixel defining film 380 and the reverse tapered side wall of the separator SEP, and an undercut structure of the groove 380-v may also be included. Thus, the upper layer may be separated once from the reverse tapered side wall of the separator SEP, and the upper layer may be separated a second time even with the undercut structure of the groove 380-v. Therefore, the upper layer may be clearly separated. As a result, the conductive layer formed on the upper portion of the separator SEP may have a structure in which the conductive layer may be more clearly separated based on the separator SEP. For example, the conductive layer may be clearly separated by the separator SEP. A gap between the upper surface of the pixel defining film 380 and the reverse tapered side wall of the separator SEP may be formed in consideration of characteristics (e.g., physical and chemical characteristics) and a thickness of the conductive layer formed on the separator SEP.

The functional layer FL, the light emitting layer EML, and the anodes Anodea and Anodeb may be stacked on the pixel defining film 380 and the separator SEP.

The light emitting layer EML may be positioned within the opening OP of the pixel defining film 380, and a second functional layer FL2 may be positioned between the cathode Cathode and the light emitting layer EML. A first functional layer FL1 may be positioned on the light emitting layer EML. The first functional layer FL1 may include a hole injection layer and/or a hole transporting layer, and the second functional layer FL2 may include an electron transporting layer and/or an electron injection layer. A combination of the functional layer FL and the light emitting layer EML may be referred to as an intermediate layer. For example, the intermediate layer may include the functional layer FL and the light emitting layer EML. In some embodiments, the first functional layer FL1 and the second functional layer FL2 may also be formed in the pixel defining film 380 and the openings OP and OPcon, and both sides thereof may be separated from each other based on the separator SEP. Although the first functional layer FL1 and the second functional layer FL2 are also positioned in the opening OPcon of the pixel defining film 380, an angle of stacking the auxiliary member TIP, the functional layer FL, and the anode Anodea may be adjusted, and the anode Anodea may be electrically connected to the connecting member CM. Thus, the anode Anodea and the connecting member CM positioned thereon may be electrically connected to each other without patterning the functional layer FL with a separate mask.

In some embodiments, the light emitting layer EML may be positioned not only within the opening OP of the pixel defining film 380, but may be formed (e.g., entirely formed) between the first functional layer FL1 and the second functional layer FL2.

A second electrode layer including the anodes Anodea and Anodeb may be formed on the first functional layer FL1 and the pixel defining film 380 in the openings OP and OPcon.

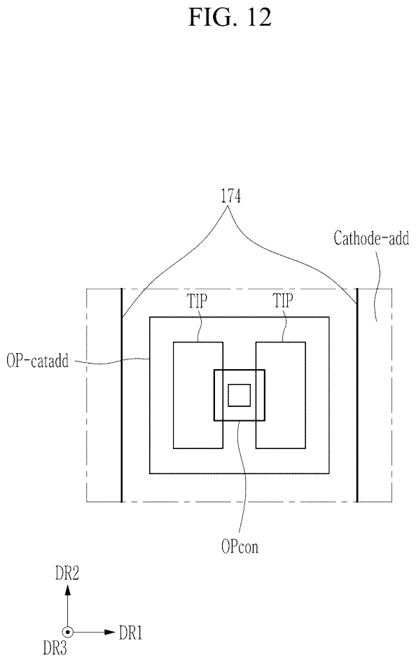

Referring to FIG. 2, the second electrode layer positioned outside the separator SEP may further include the auxiliary electrode Cathode-add. The second voltage ELVSS may be applied to the auxiliary electrode Cathode-add, and a structure in which the second voltage ELVSS is applied to the auxiliary electrode Cathode-add is described with reference to FIGS. 12 to 15.

In case that the second electrode layer including the anodes Anodea and Anodeb and the auxiliary electrode Cathode-add are stacked without a separate mask, the second electrode layer may be automatically separated by the separator SEP may be formed. For example, the second electrode layer may be automatically separated by the separator SEP without an additional mask during the manufacturing process. For example, the separator SEP may be positioned in the groove 380-v of the pixel defining film 380 together with the reverse tapered side wall of the separator SEP. Thus, since the upper surface of the pixel defining film 380 and the reverse tapered side wall of the separator SEP are separated from each other, the second electrode layer formed on the upper portion of the separator SEP may be separated into the anodes Anodea and Anodeb and the auxiliary electrode Cathode-add without a separate etching process.

Referring to FIG. 4, a portion serving as the second electrode among the semiconductor layer ACT of the transistor and the connecting member CM may be electrically connected through the opening positioned in the interlayer insulating layer 161, and a current may be transmitted to the connecting member CM through the opening OPcon to the anode Anodea. The connecting member CM and the anode Anodea may be electrically connected only in a portion thereof, and the functional layer FL may be positioned therebetween in another portion thereof. The current transmitted to the anode Anodea may pass to the cathode Cathode through the first functional layer FL1, the light emitting layer EML, and the second functional layer FL2, and the light emitting layer EML may emit light due to the current flowing through the light emitting layer EML. Thus, the light emitting element may exhibit (or display) the light having a luminance.

FIG. 4 illustrates the cross-sectional structure of the embodiment, so various modified structures may also be possible.

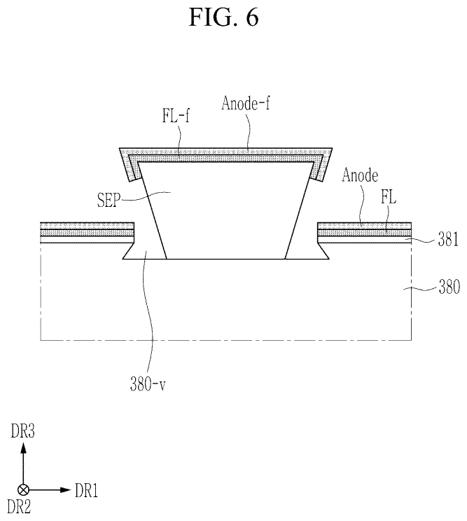

The cross-sectional structure of the opening OPcon and the separator SEP among the cross-sectional structure of FIG. 4 is described in detail with reference to FIGS. 5 and 6.

FIGS. 5 and 6 respectively illustrate a schematic enlarged cross-sectional view of a portion of FIG. 4.

The cross-sectional structure of the opening OPcon is described in detail with reference to FIG. 5 as follows.

Referring to FIG. 5, the auxiliary member TIP may be positioned on the upper portion of the planarization film 181, and protrude in a horizontal direction (e.g., a first direction DR1) on the opening exposing the connecting member CM therebelow among the planarization film 181. In FIG. 5, the auxiliary member TIP may protrude by a protruding length d. Since the auxiliary member TIP protrudes by the protruding length d, a portion of the connecting member CM positioned therebelow may be covered (e.g., covered by the protruded portion of the auxiliary member TIP). An upper surface of the auxiliary member TIP may also be exposed through the opening OPcon positioned on the pixel defining film 380.

Along the intermediate layers, the functional layer FL and the anode Anode may be sequentially stacked each other. The functional layer FL and the anode Anode may be stacked each other in a direction of an arrow shown in FIG. 5, respectively. The functional layer FL may be stacked in a direction EL-d. The anode Anode may be stacked in a direction Cat-d. For example, the EL-d direction may be different from the direction Cat-d. Since the functional layer FL and the anode Anode are stacked in different directions, ranges of the two stacked layers below the protruding auxiliary member TIP may be different from each other. For example, the stacked direction EL-d of the functional layer FL may be inclined from the upper surface of the substrate 110 at an angle closer to the third direction DR3 than the stacked direction Cat-d of the anode Anode. Thus, the functional layer FL formed below the auxiliary member TIP may be narrower than the anode Anode, and the anode Anode may be formed in a wider area than that of the functional layer FL. Therefore, as shown in FIG. 5, a portion among the side surfaces of the connecting member CM may be in direct contact with the anode Anode, and the connecting member CM and the anode Anode may be electrically connected to each other. For example, even if the functional layer FL is not removed with a separate mask, the anode Anode positioned thereon may contact (e.g., directly contact) and be electrically connected to the connecting member CM. The functional layer FL may be positioned between the connecting member CM and the anode Anode in a portion of an area in which the connecting member CM and the anode Anode overlap each other in a plan view. The connecting member CM and the anode Anode may be in direct contact in a remaining portion of the area in which the connecting member CM and the anode Anode overlap each other in a plan view.

In the above-described embodiment, the functional layer FL may be stacked before the anode Anode is formed. However, in some embodiments, the intermediate layer including the light emitting layer and the functional layer FL may be stacked before the anode Anode is formed.

A cross-sectional structure of the separator SEP portion is described in detail with reference to FIG. 6.

The groove 380-v having an undercut structure may be formed on the upper surface of the pixel defining film 380. A side wall of the groove 380-v may have a reverse tapered structure. The separator SEP may be formed in the groove 380-v (e.g., formed on an inner surface of the groove 380-v), and a side wall of the separator SEP and an upper surface of the pixel defining film 380 may be spaced apart from each other by a distance (e.g., a predetermined or selectable distance). In the cross-sectional view of FIG. 6, a width of the upper surface of the separator SEP may have a width corresponding to a width of the groove 380-v. However, in some embodiment, the width of the separator SEP may be greater or smaller than the width of the groove 380-v.

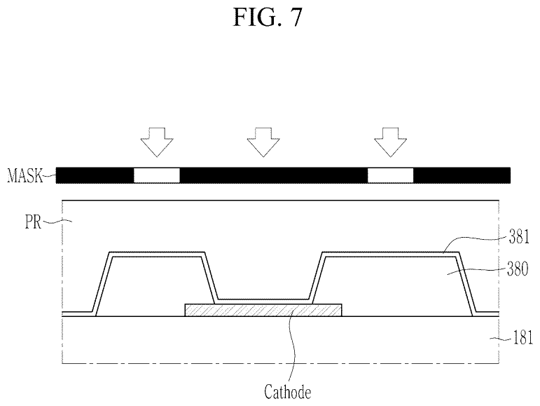

In FIG. 6, an upper inorganic film 381 may be formed on the upper surface of the pixel defining film 380. The upper inorganic film 381 may etch the groove 380-v having an undercut structure in the pixel defining film 380 by a dry etching method. The groove 380-v having the undercut structure may be formed through wet etching, and a separate inorganic film may not be positioned on the pixel defining film 380. The upper inorganic film 381 may be an inorganic insulating film including at least one of a silicon oxide (SiOₓ), a silicon nitride (SiNₓ), and a silicon oxynitride (SiOₓN_{y}). A manufacturing method of forming the groove 380-v having the undercut structure in the pixel defining film 380 is described later with reference to FIGS. 7, 8, 10, and 11.

In case that the functional layer FL and the anode Anode may be sequentially stacked on the separator SEP as shown in FIG. 6, the functional layer FL and the anode Anode may be positioned on the upper portion of the pixel defining film 380, the upper portion of the separator SEP, and a portion of the reverse tapered side wall. However, the functional layer FL and the anode Anode may not be formed in the lower portion of the reverse tapered side wall of the separator SEP and the groove 380-v positioned in the pixel defining film 380, and the functional layer FL and the anode Anode may not be continuously formed. As a result, the functional layer FL-f and the anode Anode-f may be separated based on the separator SEP.

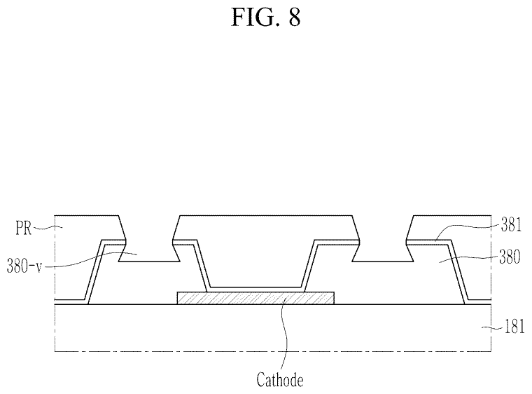

In the embodiment of FIG. 6, the upper inorganic film 381 may be formed on the upper surface of the pixel defining film 380, and this structure (e.g., the upper inorganic film 381 formed on the upper surface of the pixel defining film 380) may be formed through the same process as in FIGS. 7 and 8.

FIGS. 7 and 8 illustrate drawings of a manufacturing method for forming a pixel defining film of a light emitting display device according to an embodiment.

Referring to FIG. 7, the cathode Cathode may be formed on the planarization film 181 positioned on a substrate, and the pixel defining film 380 having an opening exposing a portion of the cathode Cathode may be formed. The upper inorganic film 381 and a photoresist PR that cover the pixel defining film 380 may be stacked, and the photoresist PR may be exposed by using a mask MASK.

Referring to FIG. 8, in case that the exposed photoresist PR is developed, the photoresist PR of the exposed portion may be removed.

The upper inorganic film 381 and the pixel defining film 380 therebelow may be dry-etched using the photoresister PR, which is partially removed, as a mask (e.g., an etching mask). Thus, the groove 380-v may be formed. The groove 380-v may have an undercut structure on the upper surface of the pixel defining film 380 and the reverse tapered side wall structure.

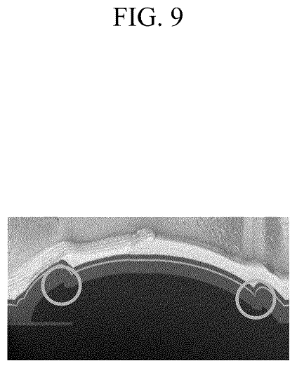

In case that dry etching and wet etching are compared, the wet etching may realize a structure in which an etched portion is undercut, but the dry etching hardly generates undercut. For example, in case that an inorganic film is etched, the undercut may not be generated by the dry etching but may be generated in the wet etching. However, in case that the organic film is etched by dry etching, an undercut may be generated although the undercut may be smaller than that of wet etching. The undercut formed by the dry etching is described in more detail with reference to FIG. 9 in which the dry etched structure is photographed.

FIG. 9 illustrates a schematic image of an undercut structure occurring during dry etching.

FIG. 9 is a photograph image taken after dry etching of the organic film. In a circled portion of FIG. 9, some undercuts occur even by dry etching.

A partial area of the organic film may be additionally etched due to gas activated during dry etching and the undercut may occur.

However, the upper inorganic film 381 may be formed (or should be formed) on the pixel defining film 380 and the pixel defining film 380 may be dry-etched (e.g., the dry etching may be performed). The upper inorganic film 381 made of an inorganic insulating material may be etched before the pixel defining film 380 made of an organic material is etched. Thus, the upper inorganic film 381 may check a time at which the pixel defining film 380 is etched and a depth of the groove 380-v formed in the pixel defining film 380 may be adjusted.

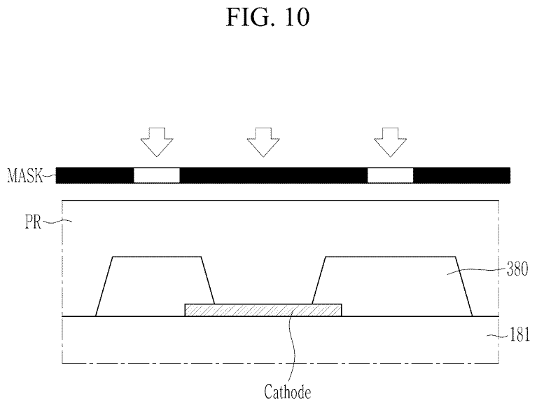

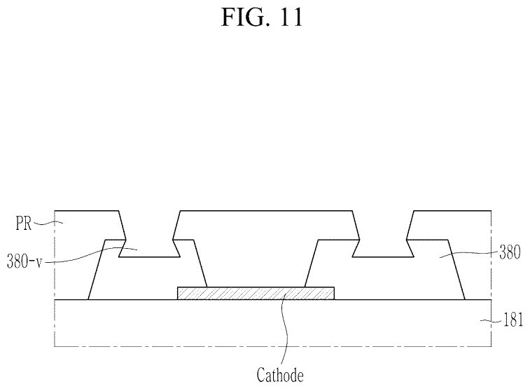

Unlike the embodiment of FIG. 6, a separate upper inorganic film (e.g., the upper inorganic film 381) may not be included on the upper surface of the pixel defining film 380, and the structure without the separate upper inorganic film may be formed through the same process as in FIGS. 10 and 11.

FIGS. 10 and 11 illustrate schematic views of a manufacturing method for forming a pixel defining film of a light emitting display device according to another embodiment.

Referring to FIG. 10, the cathode Cathode may be formed on the planarization film 181 positioned on a substrate, and the pixel defining film 380 having an opening exposing a portion of the cathode Cathode may be formed. A photoresist PR covering the pixel defining film 380 may be stacked, and the photoresist PR may be exposed by using a mask MASK.

Referring to FIG. 11, in case that the exposed photoresist PR is developed, the photoresist PR of the exposed portion may be removed.

The pixel defining film 380 disposed below the photoresist PR may be wet-etched using the photoresist PR, which is partially removed, as a mask (e.g., an etching mask). Thus, the groove 380-v may be formed in the upper surface of the pixel defining film 380. The groove 380-v may have an undercut structure and an inverse tapered side wall structure. Thus, the undercut 380-v (e.g., the undercut 380-v formed by the dry etching) may be larger than that of a groove formed by wet etching.

Referring to FIG. 2, the auxiliary electrode Cathode-add may be formed and the second voltage ELVSS may be applied to the auxiliary electrode Cathode-add. Detailed description of the auxiliary electrode Cathode-add and the second voltage ELVSS is provided below with reference to FIGS. 12 to 15.

FIGS. 12 to 15 illustrate schematic views of a structure through which a second voltage is transmitted.

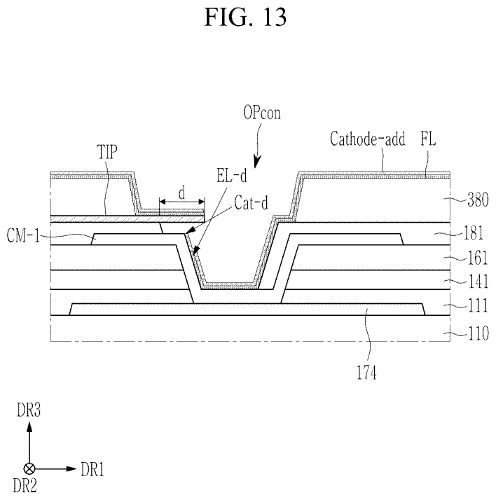

In FIGS. 12 to 15, two embodiments having different structures are described, and a structure in which the second voltage ELVSS is applied to the auxiliary electrode Cathode-add is described through the embodiment of FIGS. 12 and 13.

In the embodiment of FIGS. 12 and 13, the auxiliary member TIP (e.g., an auxiliary member for second voltage connection) may have a tip structure in which at least a portion thereof overlaps the opening OPcon (e.g., a second voltage connecting opening) in a plan view and protrude in a cross-sectional view.

Referring to FIGS. 12 and 13, the auxiliary member TIP may be positioned in an opening OP-catadd positioned on the cathode Cathode in a plan view. The auxiliary member TIP and the cathode Cathode may be made of a same material. The auxiliary member TIP may at least partially overlap the opening OPcon in a plan view.

The auxiliary member TIP may be positioned on the upper portion of the opening OPcon and protrude from an upper portion of a portion of the opening OPcon. The auxiliary member TIP may not be formed along the side wall of the opening OPcon, and may protrude in a horizontal direction (e.g., the first direction DR1) from the side wall of the opening OPcon. For example, the auxiliary member TIP may protrude at an angle corresponding to the first direction DR1. As described above, the auxiliary member TIP has a structure protruding at the upper portion of the opening OPcon. Thus, in case that layers (e.g., the functional layer FL and the auxiliary electrode Cathode-add) are formed in the opening OPcon, each of the layers may be adjusted and formed (e.g., appropriately adjusted and formed) below the auxiliary member TIP, and the layers may be electrically connected to the auxiliary electrode Cathode-add.

For example, referring to FIG. 13, the auxiliary member TIP may be positioned on the upper portion of the planarization film 181, and protrude in a horizontal direction (e.g., in a first direction DR1) on the opening exposing a connecting member CM-1 therebelow among the planarization film 181. In FIG. 13, the auxiliary member TIP may protrude by a protruding length d. Since the auxiliary member TIP protrudes by the protruding length d, a portion of the connecting member CM-1 positioned therebelow may be covered (e.g., covered by the protruded portion of the auxiliary member TIP). An upper surface of the auxiliary member TIP may also be exposed through the opening OPcon positioned on the pixel defining film 380.

Among the intermediate layers, the functional layer FL and the auxiliary electrode Cathode-add may be sequentially stacked each other. The functional layer FL and the auxiliary electrode Cathode-add may be stacked each other in a direction of an arrow shown in FIG. 13, respectively. The functional layer FL may be stacked in a direction EL-d. The auxiliary electrode Cathode-add may be stacked in a direction Cat-d. For example, the direction EL-d may be different from the direction Cat-d. Since the functional layer FL and the auxiliary electrode Cathode-add are stacked in different directions, ranges of the two stacked layers below the protruding auxiliary member TIP may be different from each other. For example, the stacked direction EL-d of the functional layer FL may be inclined from the upper surface of the substrate 110 at an angle closer to the third direction DR3 than the stacked direction Cat-d of the auxiliary electrode Cathode-add. Thus, the functional layer FL formed below the auxiliary member TIP may be narrower than the auxiliary electrode Cathode-add, and the auxiliary electrode Cathode-add may be formed in a wider area than that of the functional layer FL. Accordingly, as shown in FIG. 13, a portion among a side surface of the connecting member CM-1 may be in contact with the auxiliary electrode Cathode-add, so the connecting member CM-1 and the auxiliary electrode Cathode-add may be electrically connected to each other. For example, even if the functional layer FL is not removed with a separate mask, the auxiliary electrode Cathode-add positioned thereon may contact (e.g., directly contact) and be electrically connected to the connecting member CM-1. The functional layer FL may be positioned between the connecting member CM-1 and the auxiliary electrode Cathode-add in a portion of an area in which the connecting member CM-1 and the auxiliary electrode Cathode-add overlap each other in a plan view. The connecting member CM-1 and the auxiliary electrode Cathode-add may be in direct contact in a remaining portion of the area in which the connecting member CM-1 and the auxiliary electrode Cathode-add overlap.

Since the connecting member CM-1 is electrically connected to the driving low voltage line 174 to which the second voltage ELVSS is applied, the second voltage ELVSS may be transmitted to the auxiliary electrode Cathode-add.

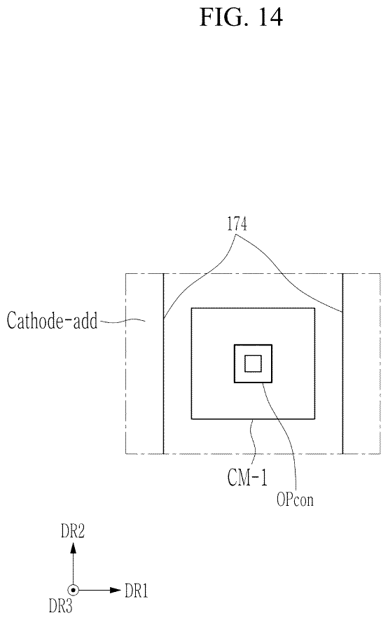

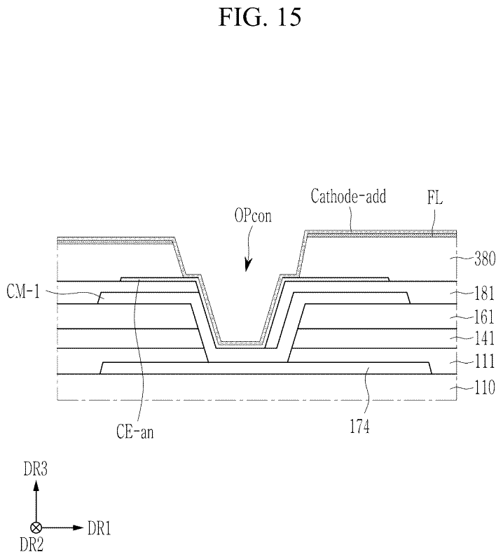

The structure in which the second voltage ELVSS is applied to the auxiliary electrode Cathode-add may have the structure shown in FIGS. 14 and 15 below, unlike FIGS. 12 and 13.

In the embodiment of FIGS. 14 and 15, the functional layer FL may be removed from the vicinity of the opening OPcon by using a separate etching process without the auxiliary member TIP (e.g., refer to FIG. 13) that partially overlaps the opening OPcon in a plan view and protrudes toward the opening OPcon. Thus, the connecting member CM-1 and the auxiliary electrode Cathode-add may be in direct contact with each other. In the embodiment of FIGS. 14 and 15, the functional layer FL may not be positioned between the connecting member CM-1 and the auxiliary electrode Cathode-add in the opening OPcon.

Referring to FIGS. 14 and 15, the planarization film 181 may be positioned on the connecting member CM-1 and have an opening to expose the connecting member CM-1. An additional connecting member CE-an and the cathode Cathode may be made of a same material and be positioned on a same layer. The opening OPcon exposing the additional connecting member CE-an may be formed in the pixel defining film 380. The functional layer FL and the auxiliary electrode Cathode-add may be formed on the pixel defining film 380. The functional layer FL may be etched so as to not be formed in the opening OPcon of the pixel defining film 380. For example, the auxiliary electrode Cathode-add may also be formed in the opening OPcon of the pixel defining film 380 and be electrically connected to the additional connecting member CE-an exposed by the opening OPcon.

Since the connecting member CM-1 is electrically connected to the driving low voltage line 174 to which the second voltage ELVSS is applied, the second voltage ELVSS may be transmitted to the auxiliary electrode Cathode-add through the connecting member CM-1 and the additional connecting member CE-an.

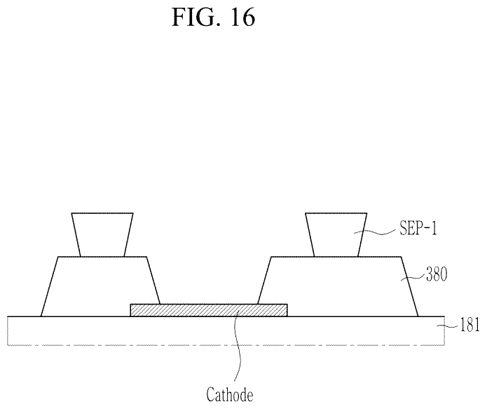

Hereinafter, a structure of a separator of a comparative example is described with reference to FIGS. 16 and 17, and difference between the structures of the separators of the embodiment and the comparative example is described.

FIG. 16 illustrates a schematic cross-sectional view of a light emitting display device according to a comparative example, and FIG. 17 schematically illustrates a photograph of a conductive layer around a separator of a comparative example.

Unlike the separator SEP of FIG. 6, a separator SEP-1 according to the comparative example of FIG. 16 may not have a groove in the pixel defining film 380 and a lower surface of the separator SEP-1 may be in contact with the upper surface of the pixel defining film 380. Thus, a lateral side of the separator SEP-1 may be electrically connected to the upper surface of the pixel defining film 380.

The separator SEP-1 of the comparative example may have a reverse tapered side wall and the conductive layer formed thereon may be separated. However, in a portion of the separators SEP-1, a conductive layer ELEC may not be broken and continuously formed as shown in FIG. 17.

However, in the separator SEP according to the embodiment of FIG. 6, the upper conductive layer may be separated from the reverse tapered side wall of the separator SEP, and the upper conductive layer may be separated by the undercut structure of the groove 380-v. Thus, the upper conductive layer may be separated by the double separation (e.g., the separation by the reverse tapered side wall of the separator SEP and the separation by the undercut structure of the groove 380-v). Therefore, the upper layer may be clearly separated and the conductive layer may be clearly separated. For example, the conductive layer of FIG. 6 may not be electrically connected around the separator as shown in FIG. 17.

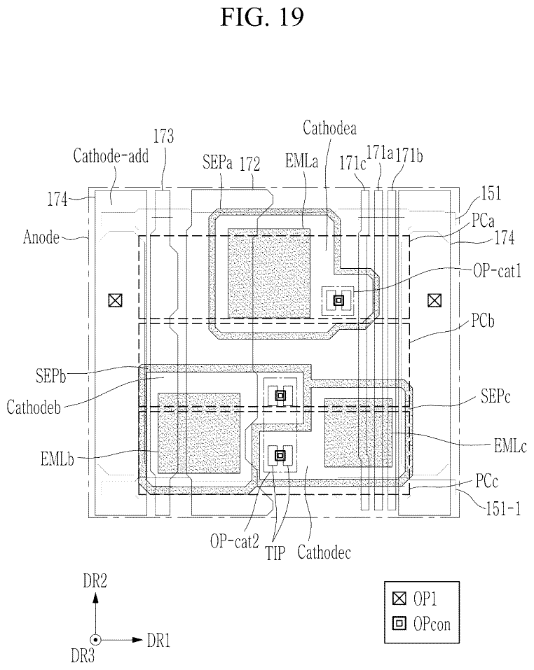

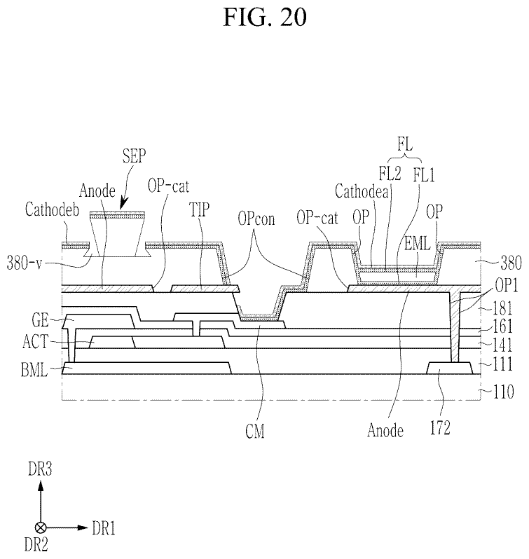

In the above description, the cathode Cathode may be positioned below the pixel defining film 380 and the anode Anode may be positioned on the pixel defining film 380. However, referring to FIGS. 19 and 20, the anode Anode may be positioned below the pixel defining film 380, and the cathode Cathode may be positioned on the pixel defining film 380. In other embodiments, a first electrode or a first light emitting electrode may be positioned below the pixel defining film 380, and a second electrode or a second light emitting electrode may be positioned on the pixel defining film 380.

In the above, the embodiment in which the output current of the pixel driver is transmitted to the anode of the light emitting element and the cathode receives the second voltage ELVSS has been described.

Hereinafter, an embodiment in which the output current of the pixel driver is transmitted to the cathode of the light emitting element and the anode receives the first voltage ELVDD, for example, an embodiment having an inverted pixel structure is described below.

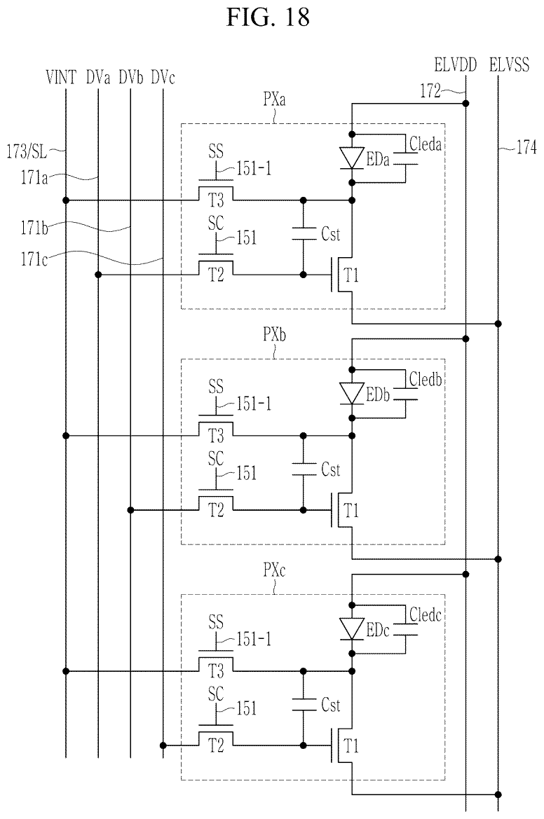

In an inverted pixel, light emitting elements Eda, Edb, and Edc may display luminance according to an amount of the current flowing through the current path electrically connected from the driving voltage line 172 to the driving low voltage line 174 through the first transistor T1. The first voltage ELVDD may be applied to the driving voltage line 172 and the second voltage ELVSS may be applied to the driving low voltage line 174. In case that the current flowing through the current path increases, the displayed luminance may increase. In the inverted pixel structure of FIG. 18, since the first electrode of the first transistor T1 is electrically connected to the light emitting elements Eda, Edb, and Edc, and is separated from the second electrode (e.g., a source electrode) of the first transistor T1, in case that a voltage of each part of the pixel driving circuit is changed, a voltage of the second electrode (e.g., the source electrode) of the first transistor T1 may not be changed.

A circuit structure of the inverted pixel is described with reference to FIG. 18.

In the embodiment of FIG. 18, the light emitting elements Eda, Edb, and Edc may be positioned between the driving voltage line 172 and the first electrode of the driving transistor T1. The driving voltage line 172 may transmit the first voltage ELVDD. The anodes of the light emitting elements Eda, Edb, and Edc may be electrically connected to the driving voltage line 172, and the cathodes of the light emitting elements Eda, Edb, and Edc may be electrically connected to the first electrode of the driving transistor T1. The initialization transistor T3 may be electrically connected to the cathodes of the light emitting elements Eda, Edb, and Edc.

For example, detailed description of the circuit structure of the inverted pixel according to the embodiment of FIG. 18 is provided below.

The gate electrode of the driving transistor T1 may be electrically connected to one end of the storage capacitor Cst, and may also be electrically connected to the second electrode (e.g., an output side electrode) of the input transistor T2. The first electrode of the driving transistor T1 may be electrically connected to the cathodes of the light emitting elements Eda, Edb, and Edc, the other end of the storage capacitor Cst, and the first electrode of the initialization transistor T3. The second electrode of the driving transistor T1 may be electrically connected to the driving low voltage line 174 that transmits the second voltage ELVSS. The gate electrode of the driving transistor T1 may receive a data voltage DVa, DVb, or DVc according to a switching operation of the input transistor T2, and a driving current may be supplied to the light emitting element Eda, Edb, or Edc according to the voltage of the gate electrode thereof. The storage capacitor Cst may store and maintain the voltage of the gate electrode of the driving transistor T1.

The gate electrode of the input transistor T2 may be electrically connected to a first scan signal line 151 that transmits a first scan signal SC. The first electrode of the input transistor T2 may be electrically connected to the data lines 171a, 171b, and 171c that transmit the data voltages DVa, DVb, and DVc, and the second electrode of the input transistor T2 may be electrically connected to an end of the storage capacitor Cst and the gate electrode of the driving transistor T1. Data lines 171a, 171b, and 171c may transmit data voltages DVa, DVb, and DVc, respectively. For example, the data lines 171a, 171b, and 171c may transmit different data voltages DVa, DVb, and DVc, respectively. The input transistors T2 of the pixels PXa, PXb, and PXc may be respectively and electrically connected to different data lines 171a, 171b, and 171c. The gate electrodes of the input transistors T2 of the pixels PXa, PXb, and PXc may be electrically connected to the first scan line 151 to receive the first scan signal SC at a same timing. Even in case that the input transistors T2 of the pixels PXa, PXb, and PXc are simultaneously turned on by the first scan signal SC of the same timing, the different data voltages DVa, DVb, and DVc may be applied to the gate electrodes of the driving transistors T1 of the pixel PXa, PXb, and PXc and one end of the storage capacitor Cst through the different data lines 171a, 171b, and 171c.

The gate electrode of the initialization transistor T3 may be electrically connected to a second scan signal line 151-1 that transmits a second scan signal SS. The first electrode of the initialization transistor T3 may be electrically connected to the other end of the storage capacitor Cst, the first electrode of the driving transistor T1, the cathodes of the light emitting elements Eda, Edb, and Edc, and one ends of the light emitting capacitors Cleda, Cledb, and Cledc. The second electrode of the initialization transistor T3 may be electrically connected to an initialization voltage line 173 that transmits an initialization voltage VINT. The initialization transistor T3 may be turned on according to the second scan signal SS to transmit the initialization voltage VINT to the cathodes of the light emitting elements Eda, Edb, and Edc, one ends of the light emitting capacitors Cleda, Cledb, and Cledc, and the other end of the storage capacitor Cst. Thus, the voltage of the cathodes of the light emitting elements Eda, Edb, and Edc may be initialized.

The initialization voltage line 173 may sense a voltage of the cathode of the light emitting element Eda, Edb, or Edc before the initialization voltage VINT is applied. Thus, the initialization voltage line 173 may serve as a sensing wire SL. In case that the voltage of the cathode of the light emitting element Eda, Edb, or Edc is sensed, the sensing wire SL may check whether the cathode voltage is maintained at a target voltage. The sensing operation and the initialization operation of transmitting the initialization voltage VINT may be performed separately in time. For example, the initialization operation may be performed after the sensing operation is performed.

In the embodiment of FIG. 18, turn-on periods of the initialization transistor T3 and of the input transistor T2 may be separated, and a writing operation performed by the input transistor T2 and an initialization operation (and/or sensing operation) performed by the initialization transistor T3 may be performed at different timings.

One end of the storage capacitor Cst may be electrically connected to the gate electrode of the driving transistor T1 and the second electrode of the input transistor T2. The other end of the storage capacitor Cst may be electrically connected to the first electrode of the initialization transistor T3, the first electrode of the driving transistor T1, the cathodes of the light emitting elements Eda, Edb, and Edc, and one ends of the light emitting capacitors Cleda, Cledb, and Cledc.

The anodes of the light emitting elements Eda, Edb, and Edc may be electrically connected to the driving voltage line 172 that applies the first voltage ELVDD, and the cathodes of the light emitting elements Eda, Edb, and Edc may be electrically connected to the first electrode of the driving transistor T1. The light emitting elements Eda, Edb, and Edc may emit light according to an output current of the driving transistor T1 to display a grayscale. The light emitting part capacitors Cleda, Cledb, and Cledc may be formed at respective ends of the light emitting elements Eda, Edb, and Edc. Thus, voltages at respective ends of the light emitting elements Eda, Edb, and Edc may be maintained constant and the light emitting elements Eda, Edb, and Edc may display a constant luminance.

Hereinafter, a planar structure and a cross-sectional structure of the pixel of the inverted structure as shown in FIG. 18 is described with reference to FIGS. 19 and 20, respectively.

A planar structure thereof is described with reference to FIG. 19.

FIG. 19 illustrates a schematic plan view of a display area of the light emitting display device according to the embodiment of FIG. 18.

The embodiment of FIG. 19 is different from the embodiment of FIG. 2 at least in that respective cathodes Cathodea, Cathodeb, and Cathodec of the light emitting elements Eda, Edb, and Edc are separated by separators SEPa, SEPb, and SEPc, and respective cathodes Cathodea, Cathodeb, and Cathodec are positioned in the separators SEPa, SEPb, and SEPc.

In FIG. 19, an area of each of the pixel drivers PCa, PCb, and PCc included in the pixel is shown with a dotted line, and cathodes Cathodea, Cathodeb, and Cathodec and the anode Anode among the light emitting elements Eda, Edb, and Edc electrically connected to the pixel drivers PCa, PCb, and PCc are shown.

Each of the cathodes Cathodea, Cathodeb, and Cathodec of the embodiment may be positioned below the pixel defining film 380 (e.g., refer to FIG. 20). For example, referring to FIGS. 19 and 20, the light emitting element may include the light emitting layer EML (e.g., FIG. 20), the anode Anode, and the cathode Cathodea, Cathodeb, or Cathodec. The anode Anode may be positioned below the light emitting layer, and the cathodes Cathodea, Cathodeb, and Cathodec may be positioned on the light emitting layer.

In FIG. 19, the anode Anode may have the openings OP-cat1 and OP-cat2 (e.g., contact openings) and be formed in the display area (e.g., an entire area of the display area). As a result, the anode Anode may be formed (e.g., entirely formed) in an area excluding the openings OP-cat1 and OP-cat2. The cathodes Cathodea, Cathodeb, and Cathodec positioned on the light emitting layer may receive a current from the pixel circuit parts PCa, PCb, and PCc through the opening OP-cat1 and OP-cat2 of the anode Anode. The pixel circuit parts PCa, PCb, and PCc may be positioned under the pixel defining film 380.

In the embodiment of FIG. 19, the first pixel driver PCa may be electrically connected to the first cathode Cathodea through the opening OPcon (e.g., a connector opening) and the opening OP-cat1 positioned in the anode Anode. The second pixel driver PCb may be electrically connected to the second cathode Cathodeb through the opening OPcon and the opening OP-cat2 positioned in the anode Anode. The third pixel driver PCc may be electrically connected to the third cathode Cathodeb through the opening OPcon and the opening OP-cat2 positioned in the anode Anode.

The first light emitting element may include the anode Anode, the first light emitting layer EMLa, and the first cathode Cathodea. The second light emitting element may include the anode Anode, the second light emitting layer EMLb, and the second cathode Cathodeb. The third light emitting element may include the anode Anodec, the third light emitting layer EMLc, and the third cathode Cathodec.

The anode Anode may be formed in the display area (e.g., the entire display area excluding the openings OP-cat1 and OP-cat2). Referring to FIG. 20, the anode Anode may be electrically connected to the driving voltage line 172 positioned therebelow through the opening OP1 to receive the first voltage ELVDD.

The separators SEPa, SEPb, and SEPc may be positioned in a groove 380-v (e.g., refer to FIG. 20) of the pixel defining film 380 (e.g., refer to FIG. 20), and may have a reversely tapered side wall. The separators SEPa, SEPb, and SEPc each may form a closed curved line in a plan view, and the cathodes may be separated based on the separators SEPa, SEPb, and SEPc. The separators SEPa, SEPb, and SEPc may be separated from each other at a distance (e.g., a predetermined or selectable distance). In FIG. 19, the separators SEPa, SEPb, and SEPc may share at least some of the separators SEPa, SEPb, and SEPc with each other.

In a plan view, the first cathode Cathodea may be positioned inside the first separator SEPa, the second cathode Cathodeb may be positioned inside the second separator SEPb, and the third cathode Cathodec may be positioned inside the third separator SEPc. An auxiliary electrode Cathode-add may be disposed at the outside of the separators SEPa, SEPb, and SEPc. The auxiliary electrode Cathode-add and the cathodes Cathodea, Cathodeb, and Cathodec may be made of a same material. The auxiliary electrode Cathode-add may receive the second voltage ELVSS which has the same voltage as the cathode. In some embodiments, the auxiliary electrode Cathode-add may be applied with different voltages from an adjacent auxiliary electrode or may be a floating electrode (or may be floated).

The first cathode Cathodea and the first light emitting layer EMLa may be positioned inside the first separator SEPa in a plan view. The first cathode Cathodea, the first light emitting layer EMLa, and the anode Anode positioned under the first light emitting layer EMLa may configure the first light emitting element. The first cathode Cathodea of the first light emitting element may be electrically connected to the first pixel driver PCa through the opening OP-cat1 positioned at the anode Anode and may receive a current from the first pixel driver PCa.

The second cathode Cathodeb and the second light emitting layer EMLb may be positioned inside the second separator SEPb in a plan view. The second cathode Cathodeb, the second light emitting layer EMLb, and the anode Anode positioned under the second light emitting layer EMLb may configure the second light emitting element. The second cathode Cathodeb of the second light emitting element may be electrically connected to the second pixel driver PCb through the opening OP-cat2 positioned at the anode Anode and may receive a current from the second pixel driver PCb.

The third cathode Cathodec and the third light emitting layer EMLc may be positioned inside the third separator SEPc in a plan view. The third cathode Cathodec, the third light emitting layer EMLc, and the anode Anode positioned under the third light emitting layer EMLc may configure the third light emitting element. The third cathode Cathodec of the first light emitting element may be electrically connected to the third pixel driver PCc through the opening OP-cat2 positioned in the anode Anode and may receive a current from the third pixel driver PCc.

Referring to FIG. 19, the pixel drivers PCa, PCb, and PCc may be electrically connected to the cathodes Cathodea, Cathodeb, and Cathodec through the openings OPcon in the openings OP-cat1 and OP-cat2 positioned in the anode Anode in a plan view. The auxiliary member TIP and the anode Anode may be made of a same material. The auxiliary member TIP may be formed on the opening OPcon and have a tip structure that at least partially overlaps the opening OPcon in a plan view and protrudes in a cross-sectional view. The auxiliary member TIP and a structure therearound may have the same planar structure as in FIG. 3 and the same cross-sectional structure as in FIG. 5.

The auxiliary member TIP may be positioned at an upper portion of the opening OPcon and protrude at the upper portion of a portion of the opening OPcon. The auxiliary member TIP may not be formed along a side wall of the opening OPcon, and may protrude at an angle equivalent to the horizontal direction from the side wall of the opening OPcon. As described above, since the auxiliary member TIP protrudes at the upper portion of the opening OPcon, in case that layers are positioned in the opening OPcon, each of the layers may be appropriately adjusted and formed below the auxiliary member TIP, and the auxiliary member TIP may be electrically connected the cathodes (e.g., the cathode Cathodeb, or the like).

For example, as shown in FIG. 5, the auxiliary member TIP may be positioned on the upper portion of the planarization film 181, and protrude in a horizontal direction (e.g., in the first direction DR1) on the opening exposing the connecting member CM therebelow among the planarization film 181. In FIG. 5, the auxiliary member TIP may protrude by the protruding length d. Since the auxiliary member TIP protrudes by the protruding length d, a portion of the connecting member CM positioned therebelow may be covered (e.g., covered by the protruded portion of the auxiliary member TIP). An upper surface of the auxiliary member TIP may also be exposed through the opening OPcon positioned on the pixel defining film 380.

The functional layer FL and the cathode Cathode among the intermediate layers may be sequentially stacked each other. The functional layer FL and the cathode Cathode may be stacked in directions of arrows (e.g., the directions EL-d and Cat-d of FIG. 5), respectively. The functional layer FL may be stacked in the direction EL-d, and the cathode Cathode may be stacked in the direction Cat-d. Since the functional layer FL and the cathode Cathode are stacked in different directions, ranges of the two stacked layers below the protruding auxiliary member TIP may be different from each other. For example, the stacked direction EL-d of the functional layer FL may be inclined from the upper surface of the substrate 110 at an angle closer to the third direction DR3 than the stacked direction Cat-d of the cathode Cathode. Thus, the functional layer FL formed below the auxiliary member TIP may be narrower than the cathode Cathode, and the cathode Cathode may be formed in a wider area than that of the functional layer FL. Accordingly, a portion of the side surface of the connecting member CM may be in direct contact with the cathode Cathode, and the connecting member CM and the cathode Cathode may be electrically connected to each other. For example, even if the functional layer FL is not removed with a separate mask, the cathode Cathode positioned thereon may contact (e.g., directly contact) and be electrically connected to the connecting member CM. The functional layer FL may be positioned between the connecting member CM and the cathode Cathode in a portion of an area in which the connecting member CM and the cathode Cathode overlap each other in a plan view, and the connecting member CM and the cathode Cathode may be in direct contact in a remaining portion of the area in which the connecting member CM and the cathode Cathode overlap each other in a plan view.

A cross-sectional structure of the light emitting display is described below with reference to FIG. 20.

FIG. 20 illustrates a schematic cross-sectional view of the light emitting display device according to the embodiment of FIG. 18.

In the cross-sectional structure of FIG. 20, descriptions are made focusing on portions with differences except for the description of the same portions as in FIG. 4.

In the cross-sectional structure of FIG. 20, the light emitting element may correspond to the light emitting layer EML positioned within the opening OP of the pixel defining film 380, and the opening OP of the pixel defining film 380 may also be referred to as a light emitting area.

In FIG. 20, the driving element layer may be similar to that of FIG. 4, and FIG. 20 differs from FIG. 4 at least in that the driving voltage line 172 is shown in FIG. 20. FIG. 20 shows that the driving voltage line 172 and the lower shielding layer BML are disposed on a same layer. In some embodiments, the driving voltage line 172 and the lower shielding layer BML may be positioned on different conductive layers. The driving voltage line 172 may be electrically connected to the anode Anode.

The structure of the light emitting element layer positioned on the driving element layer in FIG. 20 is described as follows.

A first electrode layer including the anode Anode and the auxiliary member TIP may be formed on the interlayer insulating film 161. The auxiliary member TIP may be positioned within the opening OP-cat of the anode Anode and electrically separated from the anode Anode. A portion of the anode Anode may overlap the light emitting layer EML positioned within the opening OP of the pixel defining film 380 and overlap the light emitting area in a plan view. Thus, a light emitting element may be formed.

The pixel defining film 380 including the openings OP and OPcon may be formed on the first electrode layer.

The opening OP of the pixel defining film 380 may be a portion corresponding to the light emitting element and/or the light emitting area, and light may be emitted from the light emitting layer EML positioned therein. The opening OP of the pixel defining film 380 may expose a portion of the anode Anode.

The opening OPcon of the pixel defining film 380 may be an opening for exposing a portion of the auxiliary member TIP and the connecting member CM positioned on the driving element layer, and may be an opening for electrically connecting the connecting member CM and the cathode Cathode.

The pixel defining film 380 may further include the groove 380-v, and a lower surface of the separator SEP may be in contact with the inside of the groove 380-v and an upper portion of the inner surface of the groove 380-v.

The separator SEP may separate two cathodes Cathodea and Cathodeb, and include a side wall of a reverse tapered structure. The separator SEP may have the reverse tapered side wall, and the conductive layer positioned thereon may be primarily separated. In the embodiment, the lower surface of the separator SEP may be positioned in the groove 380-v of the pixel defining film 380, and the upper surface of the pixel defining film 380 and the reverse tapered side wall of the separator SEP may be separated from each other. For example, the inner side of the groove 380-v may be positioned between the upper surface of the pixel defining film 380 and the reverse tapered side wall of the separator SEP, and the groove 380-v may include the undercut structure. Thus, an additional conductive layer may be separated by the groove 380-v. Therefore, the upper layer may be separated once from the reverse tapered side wall of the separator SEP, and the upper layer may be doubly separated by the undercut structure of the groove 380-v. Thus, the upper layer may be clearly separated. As a result, the conductive layer formed on the upper portion of the separator SEP may have a structure in which the conductive layer may be more clearly separated based on the separator SEP. A gap between the upper surface of the pixel defining film 380 and the reverse tapered side wall of the separator SEP may be formed in consideration of characteristics (e.g., physical and chemical characteristics) and a thickness of the conductive layer formed on the separator SEP. The conductive layer separated by the separator SEP of the embodiment may be partially positioned even on the side wall of the separator SEP as shown in FIG. 6.

The upper inorganic film 381 may be positioned on the separator SEP, and the groove 380-v may be formed through dry etching or wet etching. The groove 380-v may be formed by the manufacturing method of FIGS. 7, 8, 10, and 11.

The functional layer FL, the light emitting layer EML, and the cathode Cathodea and Cathodeb may be stacked on the pixel defining film 380 and the separator SEP.

The light emitting layer EML may be positioned within the opening OP of the pixel defining film 380, and the first functional layer FL1 may be positioned between the anode Anode and the light emitting layer EML. The second functional layer FL2 may be positioned on the light emitting layer EML. The first functional layer FL1 may include a hole injection layer and/or a hole transporting layer, and the second functional layer FL2 may include an electron transporting layer and/or an electron injection layer. A combination of the functional layer FL and the light emitting layer EML may be referred to as an intermediate layer. In some embodiments, the first functional layer FL1 and the second functional layer FL2 may also be formed in the pixel defining film 380 and the openings OP and OPcon. For example, sides (e.g., both sides) of the first functional layer FL1 and the second functional layer FL2 may be separated from each other based on the separator SEP. Although the first functional layer FL1 and the second functional layer FL2 are also positioned in the opening OPcon of the pixel defining film 380, by adjusting an angle of stacking the auxiliary member TIP, the functional layer FL, and the cathode (Cathodea), the cathode Cathodea may be electrically connected to the connecting member CM. Thus, the cathode Cathodea and the connecting member CM positioned thereon may be electrically connected to each other without patterning the functional layer FL with a separate mask.

In some embodiments, the light emitting layer EML may be positioned not only within the opening OP of the pixel defining film 380, but may be entirely formed between the first functional layer FL1 and the second functional layer FL2.

The second electrode layer including the cathodes Cathodea and Cathodeb may be formed on the second functional layer FL2, the pixel defining film 380, and the openings OP and OPcon.

The second electrode layer positioned outside the separator SEP may further include the auxiliary electrode Cathode-add. The second voltage ELVSS may be applied to the auxiliary electrode Cathode-add, and a structure in which the second voltage ELVSS is applied to the auxiliary electrode Cathode-add may be the same as described in FIGS. 12 to 15.

In case that the second electrode layer including the cathodes Cathodea and Cathodeb and the auxiliary electrode Cathode-add are stacked without a separate mask, the separator SEP may automatically separate the second electrode layer. For example, the separator SEP and the reverse tapered side wall of the separator SEP may be positioned in the groove 380-v of the pixel defining film 380. Thus, since the upper surface of the pixel defining film 380 and the reverse tapered side wall of the separator SEP are separated from each other, the second electrode layer formed on the upper portion of the separator SEP may be separated into the cathodes Cathodea and Cathodeb and the auxiliary electrode Cathode-add without a separate etching process.

A portion of the semiconductor layer ACT may serve as the first electrode of the transistor may be electrically connected to the connecting member CM through the opening positioned in the interlayer insulating layer 161. A current may be transmitted to the connecting member CM through the opening OPcon to the cathode Cathodea. The connecting member CM and the cathode Cathodea may be electrically connected at least in a portion, and the functional layer FL may be positioned between the connecting member CM and the cathode Cathodea in another portion thereof. The current transmitted to the cathode Cathodea may pass through the second functional layer FL2, the light emitting layer EML, and the first functional layer FL1. The current may be transmitted to the anode Anode. Due to the current flowing through the light emitting layer EML, the light emitting layer EML may emit light. Thus, the light emitting element may exhibit luminance.

FIG. 20 illustrates the cross-sectional structure of the embodiment, so various modified structures may also be possible.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light emitting display device, comprising:
a first light emitting electrode positioned on a substrate;
a pixel defining film including:
a groove; and
an opening exposing a portion of the first light emitting electrode;
a separator positioned within the groove of the pixel defining film and including a side wall having a reverse tapered structure;
a light emitting layer positioned in the opening of the pixel defining film; and
a second light emitting electrode separated by the separator.

2. The light emitting display device of claim 1, wherein the groove has an undercut structure.

3. The light emitting display device of claim 2, wherein a lower surface of the separator is positioned on an inner surface of the groove.

4. The light emitting display device of claim 3, wherein an upper surface of the pixel defining film and the side wall having the reverse tapered structure of the separator are separated from each other.

5. The light emitting display device of claim 3, further comprising:
an upper inorganic film positioned on the upper surface of the pixel defining film.

6. The light emitting display device of claim 5, wherein the upper inorganic film is not positioned in the groove.

7. The light emitting display device of claim 6, wherein the upper inorganic film and the side wall having the reverse tapered structure of the separator are separated from each other.

8. The light emitting display device of claim 1, further comprising:
a driving element layer positioned between the substrate and the first light emitting electrode,
wherein the driving element layer includes:
a semiconductor layer positioned on the substrate;
a first gate insulating film positioned on the semiconductor layer;
a gate electrode positioned on the first gate insulating film;
an interlayer insulating film covering the gate electrode;
a connecting member positioned on the interlayer insulating film; and
a planarization film covering the connecting member and including an opening exposing a portion of the connecting member.

9. The light emitting display device of claim 8, further comprising:
an auxiliary member positioned on the planarization film and at least partially overlapping the opening of the planarization film in a plan view.

10. The light emitting display device of claim 9, wherein
the first light emitting electrode further includes an opening,
the auxiliary member is positioned in the opening of the first light emitting electrode, and
the auxiliary member and the first light emitting electrode are made of a same material.

11. The light emitting display device of claim 10, further comprising:
a functional layer positioned between the first light emitting electrode and the light emitting layer and between the light emitting layer and the second light emitting electrode,
wherein in the auxiliary member, a stacked direction of the second light emitting electrode and a stacked direction of the functional layer are different from each other.

12. The light emitting display device of claim 11, wherein the stacked direction of the functional layer is inclined at an angle closer to a direction perpendicular to an upper surface of the substrate than the stacked direction of the second light emitting electrode.

13. The light emitting display device of claim 12, wherein
in a portion of an area in which the second light emitting electrode and the connecting member overlap each other in a plan view, the functional layer is positioned between the second light emitting electrode and the connecting member, and
in a remaining portion of the area in which the second light emitting electrode and the connecting member overlap each other in a plan view, the second light emitting electrode and the connecting member are in direct contact with each other.

14. The light emitting display device of claim 13, further comprising:
an auxiliary member forming another voltage connection; and
an auxiliary electrode separated by the separator, wherein
the driving element layer further includes a driving low voltage line,
the auxiliary member and the first light emitting electrode are made of a same material,
the auxiliary electrode separated by the separator and the second light emitting electrode are made of a same material,
the planarization film further includes another opening to electrically connect the auxiliary electrode and the driving low voltage line, and
a portion of the auxiliary electrode for second voltage connection overlaps the another opening of the planarization film in a plan view.

15. A light emitting display device, comprising:
a semiconductor layer positioned on a substrate;
a first gate insulating film positioned on the semiconductor layer;
a gate electrode positioned on the first gate insulating film;
an interlayer insulating film covering the gate electrode;
a connecting member positioned on the interlayer insulating film;
a planarization film covering the connecting member and including an opening exposing a portion of the connecting member;
a first light emitting electrode positioned on the planarization film;
an auxiliary member positioned on the planarization film;
a pixel defining film including an opening exposing a portion of the first light emitting electrode;
a separator positioned on the pixel defining film;
a light emitting layer positioned in the opening of the pixel defining film; and
a second light emitting electrode positioned on the pixel defining film, the separator, and the light emitting layer,
wherein the auxiliary member at least partially overlaps the opening of the planarization film in a plan view.

16. The light emitting display device of claim 15, wherein
the first light emitting electrode further includes an opening,
the auxiliary member is positioned in the opening of the first light emitting electrode, and
the auxiliary member and the first light emitting electrode are made of a same material.

17. The light emitting display device of claim 16, further comprising:
a functional layer positioned between the first light emitting electrode and the light emitting layer and between the light emitting layer and the second light emitting electrode,
wherein in the auxiliary member, a stacked direction of the second light emitting electrode and a stacked direction of the functional layer are different from each other.

18. The light emitting display device of claim 17, wherein the stacked direction of the functional layer is inclined at an angle closer to a direction perpendicular to an upper surface of the substrate than the stacked direction of the second light emitting electrode.

19. The light emitting display device of claim 18, wherein
in a portion of an area in which the second light emitting electrode and the connecting member overlap each other in a plan view, the functional layer is positioned between the second light emitting electrode and the connecting member, and
in a remaining portion of the area in which the second light emitting electrode and the connecting member overlap each other in a plan view, the second light emitting electrode and the connecting member are in direct contact with each other.

20. The light emitting display device of claim 19, further comprising:
a driving low voltage line;
an auxiliary member forming another voltage connection; and
an auxiliary electrode separated by the separator, wherein
the auxiliary member and the first light emitting electrode are made of a same material,
the auxiliary electrode and the second light emitting electrode are made of a same material,
the planarization film further includes another opening to electrically connect the auxiliary electrode and the driving low voltage line, and
a portion of the auxiliary electrode for second voltage connection overlaps the another opening of the planarization film in a plan view.
